(19) United States
(12) Patent Application Publication
(10) Pub. No.: US 2007/0296003 A1
(43) Pub. Date: Dec. 27, 2007

(54) Thin Film Transistor Substrate and Method for Manufacturing the Same

(75) Inventors: Gyung-Soon Park, Yongin-si (KR); Chun-Gi You, Hwaseong-si (KR); Kyung-Kim Park, Yongin-si (KR); Hyun-Sik Yoon, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 11/760,495

(22) Filed: Jun. 8, 2007

(30) Foreign Application Priority Data
Jun. 8, 2006 (KR) 2006-51289
Jun. 8, 2006 (KR) 2006-51407

(51) Int. Cl. H01L 29/76

(52) U.S. Cl. 257/288

(57) ABSTRACT

A thin-film transistor (TFT) substrate includes a base substrate, a semiconductor layer, a gate insulating layer, a first gate electrode and a second gate electrode. The semiconductor layer is formed on the base substrate and includes source, drain, channel and low concentration doped regions. The channel region is formed between the source and drain regions. The low concentration doped region is formed between the source and channel regions and between the drain and channel regions. The gate insulating layer is formed on the semiconductor layer. The first gate electrode is formed on the gate insulating layer to be overlapped with the channel region. The second gate electrode is formed on the second gate electrode. The gate insulating layer includes first and second regions, and a thickness of the first region is thinner than that of the second region. Thus, electric characteristics of the TFT may be enhanced.

### CROSS-REFERENCE TO RELATED APPLICATIONS

This application claims priority under 35 U.S.C. § 119 to Korean Patent Application No. 2006-51289 filed on Jun. 8, 2006, and Korean Patent Application No. 2006-51407 filed on Jun. 8, 2006 in the Korean Intellectual Property Office (KIPO), the contents of both of which are herein incorporated by reference in their entirety.

### BACKGROUND OF THE INVENTION

1. Field of the Invention

Exemplary embodiments of the invention relate to a thin-film transistor (TFT) substrate and a method for manufacturing the TFT substrates and more particularly, to a TFT substrate having enhancing electric characteristics and a method for manufacturing the TFT substrate.

2. Description of the Related Art

Generally, a thin-film transistor (TFT) substrate includes a gate line transferring a driving signal, a data line transferring an image signal, a TFT electrically connected to the gate and data lines, and a pixel electrode electrically connected to the TFT.

The TFT includes a gate electrode that is a portion of the gate line, a semiconductor layer forming a channel, a source electrode that is a portion of the source electrode, and a drain electrode facing the source electrode with respect to the semiconductor layer. The semiconductor layer may be classified as either an amorphous silicon type or a polycrystalline silicon type according to a crystalline state of silicon.

A polycrystalline TFT having the semiconductor layer of the polycrystalline silicon is driven faster than an amorphous TFT having the semiconductor layer of the amorphous silicon. The polycrystalline TFT may be formed on a substrate together with the TFTs in a pixel area and a driving circuit.

However, the polycrystalline TFT has a higher off-current than that of the amorphous TFT. To handle the above situation, a low concentration doped region is formed.

Conventionally, the low concentration doped region is formed by forming an oxidized layer at sides of the gate electrode or by using a photoresist film formed on the gate electrode. However, since the above process needs an additional mask for doping, manufacturing costs are increased and manufacturing efficiency is decreased.

In addition, conventionally, adhesive strength between the gate electrode and a gate insulating layer that is formed under the gate electrode, or between the gate electrode and the photoresist film, is weak, so that the gate electrode is difficult to form into a predetermined shape. Accordingly, a source region, a drain region and the low concentration doped region that are formed by using the gate electrode as a doping mask, may be respectively formed at different portions depending on the TFT, so that electric characteristics of the TFT may be changed.

### SUMMARY OF THE INVENTION

Exemplary embodiments of the invention provide a thin-film transistor (TFT) substrate having enhancing electric characteristics. Further exemplary embodiments of the invention provide a method for manufacturing the TFT substrate.

According to an exemplary embodiment of the invention, there is provided a TFT substrate including a base substrate, a semiconductor layer, a gate insulating layer, a first gate electrode and a second gate electrode.

The semiconductor layer is formed on the base substrate, and includes a source region, a drain region, a channel region and a low concentration doped region. The channel region is formed between the source and drain regions. The low concentration doped region is formed both between the source and channel regions and between the drain and channel regions. The gate insulating layer is formed on the semiconductor layer. The first gate electrode is formed on the gate insulating layer to be overlapped with the channel region. The second gate electrode is formed on the second gate electrode.

The gate insulating layer includes a first region formed in the source and drain regions and a second region formed in the channel region, and a thickness of the first region is thinner than that of the second region.

The gate insulating layer may further include a third region formed in the low concentration doped region. The thickness of the first region is thinner than that of the third region, and the thickness of the third region is thinner than that of the second region.

According to another exemplary embodiment of the invention, there is provided a TFT substrate including a base substrate a semiconductor layer, a first gate insulating layer, a second gate insulating layer, a first gate electrode and a second gate electrode.

The semiconductor layer is formed on the base substrate and includes a source region, a drain region, a channel region and a low concentration doped region. The channel region is formed between the source and drain regions. The low concentration doped region is formed both between the source and channel regions and between the drain and channel regions. The first gate insulating layer is formed on the semiconductor layer. The second gate insulating layer is formed on the first gate insulating layer to be overlapped with the low concentration doped region of the semiconductor layer and the channel region. The first gate electrode is formed on the second gate insulating layer to be overlapped with the channel region. The second gate electrode is formed on the first gate electrode.

According to another exemplary embodiment of the invention, there is provided a method for manufacturing a TFT substrate including forming a semiconductor layer on a base substrate; forming a gate insulating layer on the semiconductor layer; sequentially depositing first and second gate metal layers on the gate insulating layer; coating a photoresist film on the second gate metal layer; patterning the photoresist film via an exposure process; forming a second gate electrode having a narrower width than that of the patterned photoresist film and a first gate metal pattern having substantially the same width as that of the patterned photoresist film, via etching of the first and second gate metal layers; forming a source region and a drain region, via doping of high concentration dopants on the semiconductor layer using the patterned photoresist film; ashing the patterned photoresist film to have substantially the same width as that of the second gate electrode; forming a first gate electrode to have substantially the in same width as that of the second gate electrode, via etching of the first gate metal pattern; removing the ashed photoresist film; and forming a low concentration doped region, via doping of low concentration dopants on the semiconductor layer using the first and second gate electrodes.

Forming the second gate electrode and the first gate metal pattern preferably include forming the second gate electrode having the narrower width than that of the patterned photoresist film, via an isotropic etching process, and forming the first gate electrode having substantially the same width as that of the patterned photoresist film, via an anisotropic etching process.

According to a further aspect of the invention, the method includes forming an insulating interlayer on the gate insulating layer and the second gate electrode, after forming the low concentration doped region; forming first and second contact holes in the insulating interlayer for exposing the source region and the drain region; forming a source electrode and a drain electrode that are electrically connected to the source and drain regions through the first and second contact holes, respectively; forming a passivation layer on the source and drain electrodes; form ing a third contact hole in the passivation layer for exposing the drain electrode; and forming a pixel electrode electrically connected to the drain electrode through the third contact hole.

According to another exemplary embodiment of the invention, there is provided a method for manufacturing a AFT substrate including forming a semiconductor layer on a base substrate; sequentially forming first and second gate insulating layers on the semiconductor layer; sequentially depositing first and second gate metal layers on the second gate insulating layer; coating a photoresist film on the second gate metal layer, patterning the photoresist film via an exposure process; forming a second gate electrode having a narrower width than that of the patterned photoresist film and a first gate metal pattern having substantially the same width as that of the patterned photoresist film, via etching of the first and second gate metal layers; patterning the second gate metal layer to have substantially the same width as that of the first gate metal pattern; ashing the patterned photoresist film to have substantially the same width as that of the second gate electrode; forming a first gate electrode to have substantially the same width as that of the second gate electrode, via etching of the first gate metal pattern; removing the ashed photoresist film; and simultaneously forming a low concentration doped region doped with dopants at a low concentration on the semiconductor layer, a source region and a drain region doped with the dopants at a low concentration on the semiconductor layer, using the first and second gate electrodes and the patterned second gate insulating layer.

### BRIEF DESCRIPTION OF THE DRAWINGS

FIG. 1 is a plan view illustrating a portion of a thin-film transistor (TFT) substrate according to a first example embodiment of the present invention.

FIG. 2 is a cross-sectional view taken along a line I-I′ of FIG. 1.

FIGS. 3A, 4A, 5A and 6A are plan views arranged according to a method for manufacturing the TFT substrate in FIG. 1.

FIG. 3B is a cross-sectional view taken along a line II-II′ of FIG. 3A.

FIGS. 4B to 4E are cross-sectional views taken along a line III-III′ of FIG. 4A, and are sequentially arranged according to manufacturing processes.

FIG. 5B is a cross-sectional view taken along a line IV-IV′ of FIG. 5A.

FIG. 6B is a cross-sectional view taken along a line V-V′ of FIG. 6A.

FIG. 7 is a plan view partially illustrating a TFT substrate according to a second example embodiment of the present invention.

FIG. 8 is a cross-sectional view taken along a line I-I′ of FIG. 7.

FIGS. 9A, 10A, 11A and 12A are plan views arranged according to a method for manufacturing the TFT substrate in FIG. 7.

FIG. 9B is a cross-sectional view taken along a line II-II′ of FIG. 9A.

FIGS. 10B, to 10E are cross-sectional views taken along a line III-III′ of FIG. 10A, and are sequentially arranged according to manufacturing processes.

FIG. 11B is a cross-sectional view taken along a line IV-IV′ of FIG. 11A.

FIG. 12B is a cross-sectional view taken along a line V-V′ of FIG. 12A.

FIG. 13 is a plan view illustrating a portion of a TFT substrate according to a third example embodiment of the present invention.

FIG. 14 is a cross-sectional view taken along a line I-I′ of FIG. 13.

FIGS. 15A to 15H are cross-sectional views illustrating a method for manufacturing the TFT substrate in FIG. 13.

FIG. 16 is a plan view illustrating a portion of a TFT substrate according to a fourth example embodiment of the present invention.

FIG. 17 is a cross-sectional view taken along a line I-I′ of FIG. 16.

FIGS. 18A to 18E are cross-sectional views illustrating a method for manufacturing the TFT substrate in FIG. 16.

### DESCRIPTION OF THE EXEMPLARY EMBODIMENTS

The invention is described more fully hereinafter with reference to the accompanying drawings, in which embodiments of the invention are shown. This invention may, however, be embodied in many different forms and should not be construed as limited to the embodiments set forth herein.

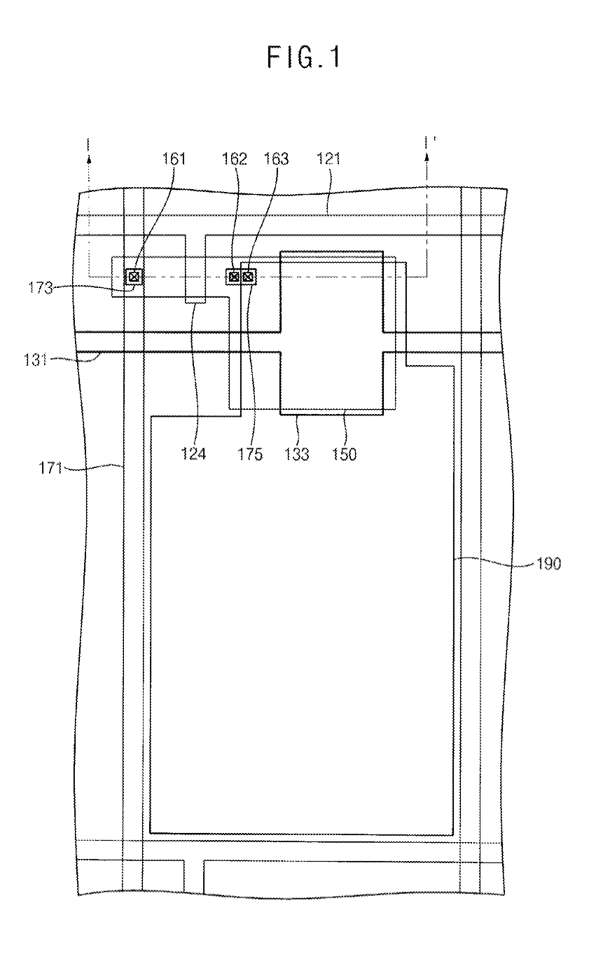

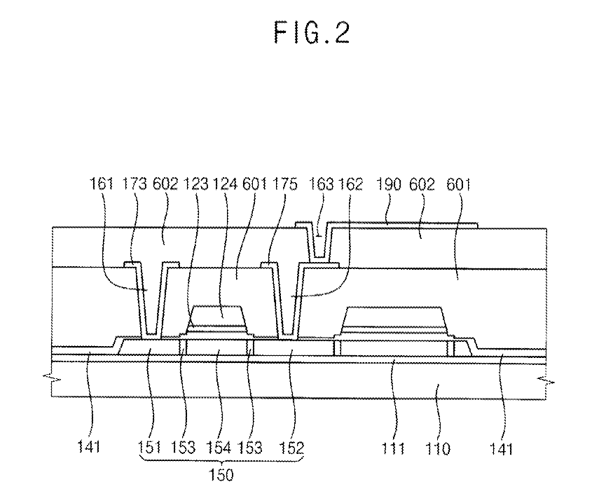

Exemplary embodiments of the invention are described herein with reference to cross-section illustrations that are schematic illustrations of idealized embodiments (and intermediate structures) of the invention. FIG. 1 is a plan view illustrating a portion of a thin-film transistor (TFT) substrate according to an example embodiment of the present invention. FIG. 2 is a cross-sectional view taken along a line I-I′ of FIG. 1.

Referring to FIGS. 1 and 2, the TFT substrate according to the example embodiment will be explained.

Referring to FIG. 1, the TFT substrate includes a TFT formed in a region where a gate line 121 transferring a driving signal crosses a data line 171 transferring an image signal.

The TFT includes a semiconductor layer 150, a gate electrode, a source electrode 173 and a drain electrode 175. The semiconductor layer includes polycrystalline silicon. The gate electrode is protruded from the gate line 121 and is overlapped with the semiconductor layer 150. The source and drain electrodes 173 and 175 make contact with the semiconductor layer 150 through a first contact hole 161 and a second contact hole 162, respectively.

In the TFT substrate according to the example embodiment, the source electrode 173 of the TFT may be formed from a portion of the data line 171, but may be formed separately from the data line 171.

The drain electrode 175 of the TFT is electrically connected to a pixel electrode 190 through a third contact hole 163. Examples of a material that can be used for the pixel electrode 190 may include indium tin oxide (ITO) or indium zinc oxide (IZO).

In a liquid crystal display (LCD) apparatus, the image signal transferred through the TFT generates an electric difference between the pixel electrode 190 and a common electrode (not shown) facing the pixel electrode 190, so that a longitudinal arrangement direction of liquid crystal molecules is changed. Thus a transmissivity of light is controlled to display the image.

In addition, in an organic light-emitting diode (OLED) apparatus, the image signal transferred through the TFT generates a current flow between the pixel electrode 190 and the common electrode facing the pixel electrode 190, so that luminance of the light emitted from an organic light emitting material disposed between the pixel electrode 190 and the common electrode is controlled. Thus, the image is displayed.

The TFT substrate according to the example embodiment further includes a subsidiary capacity electrode line 131 formed along the gate line 121. A subsidiary capacity electrode 133 electrically connected to the subsidiary capacity electrode line 131 is overlapped with the pixel electrode 190 to form a storage capacitor.

The TFT substrate includes a blocking layer 111 that is formed on a transparent insulating layer 110 and includes silicon oxide (SiOx) and silicon nitride (SiNx). The semiconductor layer 150 is formed on the blocking layer 111. The semiconductor layer 150 includes source and drain regions 151 and 152 doped with n-type or p-type dopants at a high concentration, and a channel region 154 disposed between the source and drain regions 151 and 152. In this case, the semiconductor layer 150 includes, for example, polycrystalline silicon.

A low concentration doped region 153 that is doped with the dopants at a low concentration is formed between the source and channel regions 151 and 154, and between the drain and channel regions 152 and 154.

A gate insulating layer 141 is formed on the semiconductor layer 150. The gate insulating layer 141 may include silicon oxide (SiOx) or silicon nitride (SiNx). The gate insulating layer 141 includes a first region disposed on the source and drain regions 151 and 152 of the semiconductor layer 150, a second region disposed on the channel region 154, and a third region disposed on the low concentration doped region 153.

A thickness of the gate insulating layer 141 in the first region is thinner than that of the gate insulating layer 141 in the second region, and the thickness of the gate insulating layer 141 on the third region is thinner than that of the gate insulating layer 141 in the second region. In addition, the thickness of the gate insulating layer 141 in the first region is thinner than that of the gate insulating layer 141 in the third region. The thickness differences between each region are induced by a dry etching process that patterns first and second gate electrodes 123 and 124. For example, the gate insulating layer 141 (the first region) on the source and drain regions is etched twice via the dry etching process, the gate insulating layer 141 (the third region) on the low concentration doped region is etched once via the dry etching process, and the gate insulating layer 141 (the second region) on the channel region is not etched, and thus the thickness is different in each region.

The gate line 121, the first and second gate electrodes 123 and 124, and the subsidiary capacity electrode 133 are formed on the gate insulating layer 141. The gate line 121, the first and second gate electrodes 123 and 124, and the subsidiary capacity electrode 133 are formed from a double gate-metal layer.

The first and second gate electrodes 123 and 124 are overlapped with the channel region of the semiconductor layer 150. For example, the first and second gate electrodes 123 and 124 are formed on the second region of the gate insulating layer 141.

The first gate electrode 123 formed on the gate insulating layer 141 includes metal, such as titanium (Ti) or tantalum (Ta), or an alloy thereof, to increase adhesive strength with the gate insulating layer 141. The second gate electrode 124 includes metal including at least one of molybdenum (Mo) and tungsten (W) that have low resistivity, or an alloy thereof. The second gate in electrode 124 is formed on the first gate electrode 123.

The adhesive strength between the gate insulating layer 141 and the first gate electrode 123 is very high, so that the gate electrode may be formed to have a predetermined shape in the etching process.

Alternatively, the first gate electrode 123 includes metal including at least one of molybdenum (Mo) and tungsten (W) that have low resistivity, or an alloy thereof. The second gate electrode 124 formed on the first gate electrode 123 includes metal, such as titanium (Ti) or tantalum (Ta), or an alloy thereof, to increase the adhesive strength with a photoresist film PR. In this case, the adhesive strength between the second gate electrode 124 and the photoresist film PR is very high, and thus lifting or detachment of the photoresist film may be prevented and the gate electrode may be formed to have the predetermined shape in the etching process.

A first insulating interlayer 601 is formed on the gate line 121, the gate electrodes 123 and 124, the subsidiary capacity electrode 133 and the subsidiary capacity electrode line 131. The first insulating interlayer 601 includes a first contact hole 161 and a second contact hole 162 for exposing the source region 151 and the drain region 152 of the semiconductor layer 150.

The first insulating interlayer 601 may have a single-layer or multilayer structure including silicon nitride (SiNx) or silicon oxide (SiOx).

The data line 171, which crosses the gate line 121 to define the pixel area is formed on the first insulating interlayer 601. The data line 171 is partially connected to the source region 151 through the first contact hole 161, and a portion of the data line 171 connected to the source region 151 is used as the source electrode 173 of the TFT.

The drain electrode 175 is formed from the same layer as the data line 171. The drain electrode 175 is separated from the source electrode 173 by a predetermined distance, and makes contact with the drain region 152 through the second contact hole 162.

The drain electrode 175 and the data line 171 include the same conductive layer as the gate line, such as an aluminum based metal including aluminum (Al) or aluminum alloy. The drain electrode 175 and the data line 171 may have a multilayer structure that includes at least one metal, such as chromium (Cr) titanium (Ti), tantalum (Ta) and molybdenum (Mo) that have good physical, chemical and electrical characteristics with indium tin oxide (ITO) or indium zinc oxide (IZO), or an alloy thereof.

A second insulating interlayer 602 is formed on the entire first insulating interlayer 601 on which the drain electrode 175 and the data line 171 are formed. The second insulating interlayer 602 includes the third contact hole 163 for exposing the drain electrode 175. The second insulating interlayer 602 includes silicon oxide (SiOx) or silicon nitride (SiNx), for protecting the TFT like a passivation layer.

The pixel electrode 190 electrically connected to the drain electrode 175 is formed on the second insulating interlayer 602.

The pixel electrode 190 may include indium tin oxide (ITO) or indium zinc in oxide (IZO).

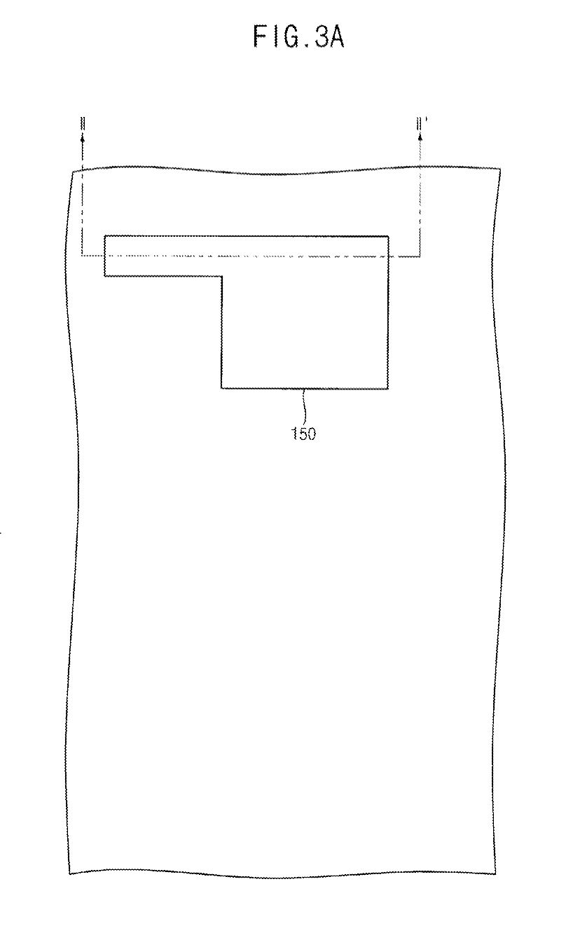

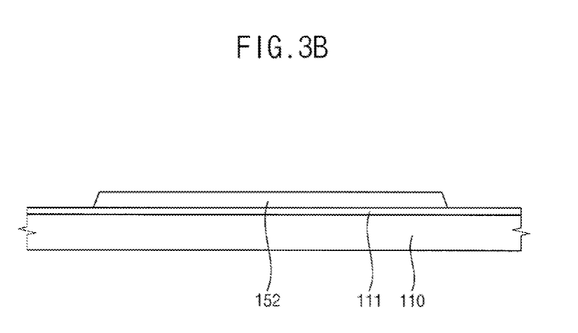

Hereinafter, a method for manufacturing the TFT substrate according to an example embodiment will be explained referring to FIGS. 3A to 6B.

FIGS. 3A, 4A, 5A and 6A are plan views arranged according to the method for manufacturing the TFT substrate according to the embodiment in FIG. 1. Particularly, FIG. 3A is a plan view illustrating the TFT substrate after forming the semiconductor layer 150 including polycrystalline silicon on the insulating substrate 110.

FIG. 3B is a cross-sectional view taken along a line II-II′ of FIG. 3A.

The blocking layer 111 and the semiconductor layer including amorphous silicon are sequentially deposited on the insulating layer 110. Then, a laser beam is irradiated onto the semiconductor layer including amorphous silicon, or heat is applied to the semiconductor layer, so that a semiconductor layer 150 including polycrystalline silicon is formed. Then, the semiconductor layer 150 is patterned to have a predetermined shape.

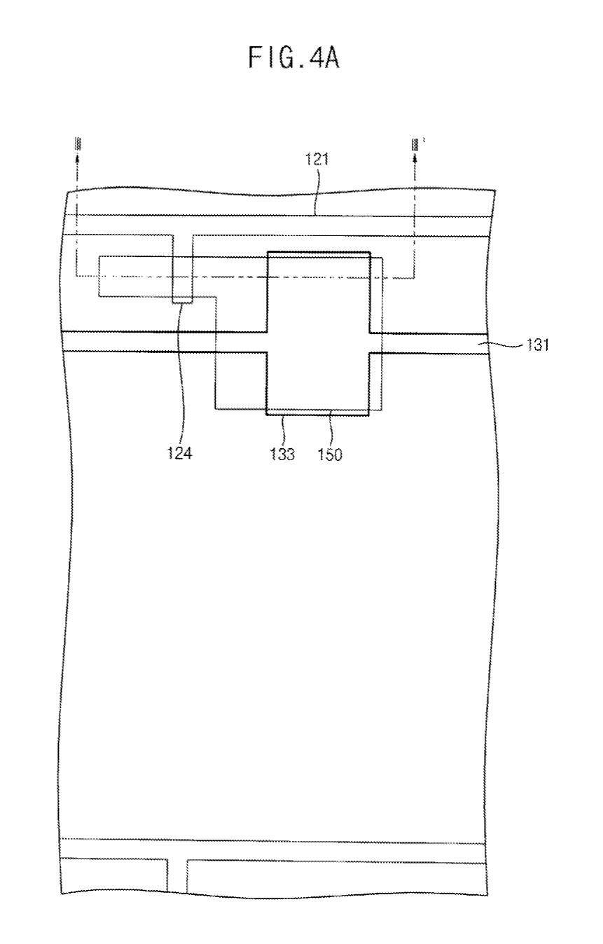

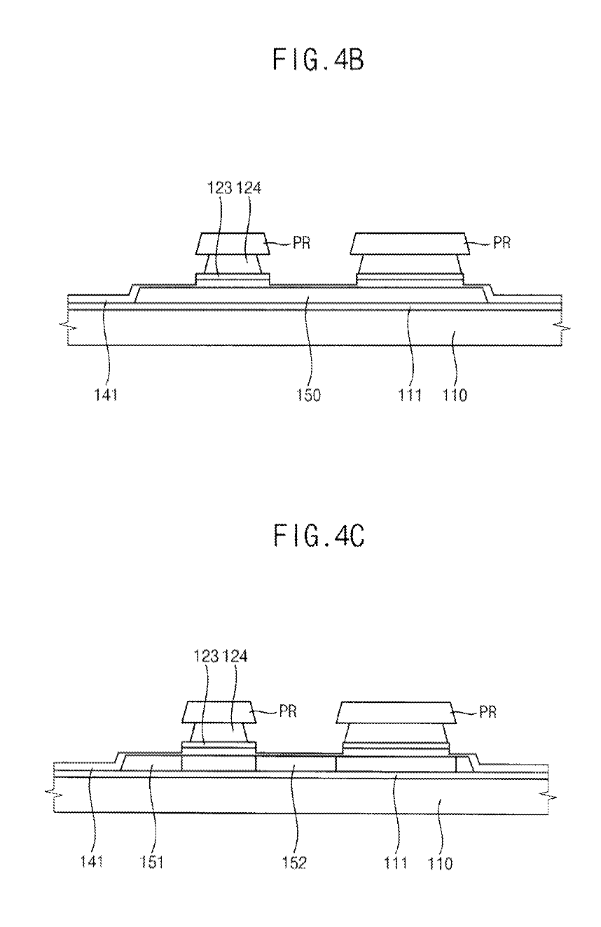

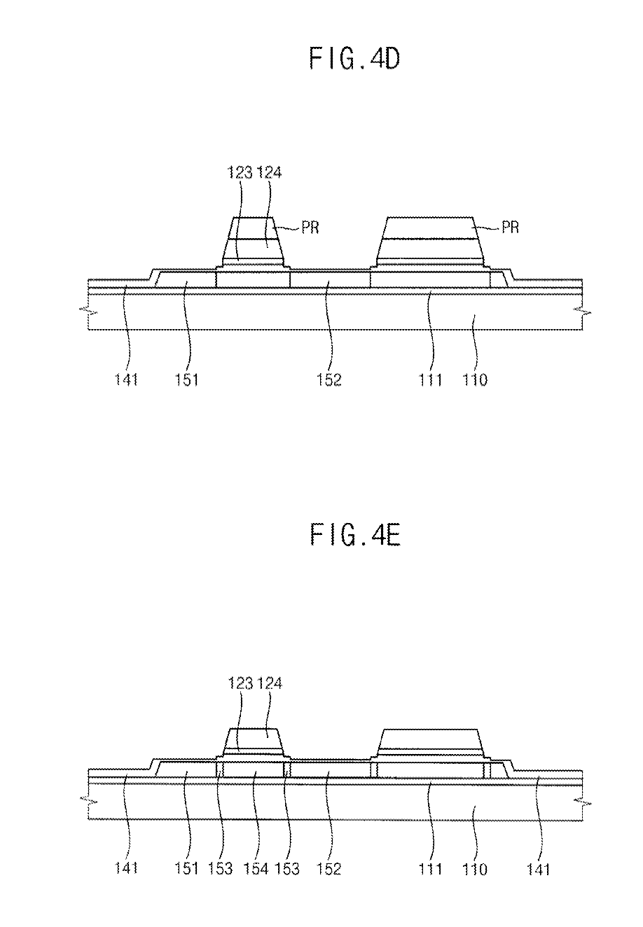

FIG. 4A is a plan view illustrating the TFT substrate after forming the gate insulating layer 141 and the first and second gate electrodes 123 and 124 on the crystallized semiconductor layer 150. FIGS. 4B to 4E are cross-sectional views taken along a line III-III′ of FIG. 4A, and are sequentially arranged according to manufacturing processes.

After the semiconductor layer 150 is patterned, the gate insulating layer 141, a first gate metal 123 and a second gate metal 124 are sequentially deposited on the blocking layer 111 and the semiconductor layer 150. The photoresist film PR is coated on the second gate metal 124, and then, the photoresist film PR is patterned by irradiating light, such as an ultraviolet (UV) ray, by using a mask.

Then, as illustrated in FIG. 48, a first gate metal pattern 123 and the second gate electrode 124 are formed via a photolithography process using the patterned photoresist film PR.

The photolithography process includes two alternative processes. The first process includes forming the second gate electrode 124 having a narrower width than that of the photoresist film PR by an isotropic etching process using the patterned photoresist film PR, then forming the first gate metal pattern 123 having substantially the same width as that of the patterned photoresist film PR by an anisotropic etching process. The second process includes forming the first gate metal pattern 123 and the second gate metal pattern 124 having substantially the same width as that of the photoresist film PR by the isotropic process using the patterned photoresist film PR, then forming the second gate electrode 124 having a narrower width than that of the photoresist film PR by the isotropic etching process.

In this case, the isotropic etching process may include a wet etching process using an etchant. A material may be etched both substantially perpendicular to the substrate and substantially parallel with the substrate in the isotropic etching process. Thus, the width of the second gate electrode 124 may be formed to be narrower than that of the photoresist film PR.

In addition, the anisotropic etching process may include a dry etching process using a gas having good reactivity. A material may be etched only substantially perpendicular to the substrate in the anisotropic etching process. A selective ratio according to the etched material in the anisotropic etching process is lower than that in the isotropic etching process. Thus, when the first gate metal pattern is patterned to have substantially the same width as that of the photoresist film, the gate insulating layer is partially etched.

FIG. 4B illustrates that the first gate metal pattern having substantially the same width as that of the patterned photoresist film is disposed under the second gate electrode having the narrower width than that of the patterned photoresist film. Alternatively, the second gate electrode having the narrower width than that of the patterned photoresist film may be disposed under the first gate metal pattern having substantially the same width than that of the patterned photoresist film.

After forming the first gate metal pattern 123 and the second gate electrode 124 by the etching process using the patterned photoresist film PR, the semiconductor layer is doped with the dopants at a high concentration by using the patterned photoresist film as the doping mask.

The dopants include an n-type dopant ion when a carrier of the TFT is an electron. The n-type dopant ion mainly includes elements corresponding to the 5B group in the periodic table of elements. In addition, the dopants include a p-type dopant ion when the carrier of the TFT is a hole. The p-type dopant ion mainly includes elements corresponding to the 3B group in the periodic table of in elements.

FIG. 4C illustrates the semiconductor layer 150 on which the source and drain regions 151 and 152 are formed by doping the dopants at a high concentration. The gate insulating layer 141, which is disposed under the first gate metal pattern 123 having substantially the same width as that of the photoresist film via the anisotropic etching process, is thicker than the gate insulating layer 141 that is disposed over the source and drain regions 151 and 152.

After forming the source and drain regions 151 and 152 on the semiconductor layer 150, the photoresist film PR is ashed to form the low concentration doped region and the channel region. Ashing is a process that shaves the photoresist film using a mixed gas of oxygen (O₂) and carbon tetrafluoride (CF₄). The photoresist film PR is formed to have substantially the same width as that of the second gate electrode 124 via the ashing process.

Then, the first gate metal pattern 123 is etched by the ashed photoresist film PR, so that the first gate electrode 123 having substantially the same width as that of the second gate electrode 124 is formed. The etching process includes the anisotropic etching process.

The gate insulating layer 141 is formed to have a stepped portion due to the characteristics of the anisotropic etching process. For example, the thickness of the gate insulating layer 141 (the first region) formed on the source and drain regions 151 and 152 is thinner than that of the gate insulating layer 141 (the third region) formed on the semiconductor layer in which the low concentration doped region is formed. In addition, the thickness of the third region is thinner than that of the gate insulating layer 141 (the second region) formed under the first and second gate electrodes 123 and 124.

FIG. 4D is a cross-sectional view illustrating the TFT substrate after ashing the photoresist film PR, and forming the first and second gate electrodes 123 and 124 using the photoresist film PR.

The ashed photoresist film PR is removed, after forming the first and second gate electrodes 123 and 124. Then, the semiconductor layer is doped with the dopants at a low concentration using the first and second gate electrodes 123 and 124 as the doping mask. In this case, the dopants have substantially the same type ion as that of the dopants used in the source and drain regions 151 and 152.

The channel region 154 of the TFT includes the semiconductor layer that is not doped with the dopants at a low concentration and on which the first and second gate electrodes 123 and 124 are formed.

In addition, the low concentration doped region 153 is formed both between the source and channel regions 151 and 154 of the semiconductor layer and between the drain and channel regions 152 and 154 of the semiconductor layer.

FIG. 4E is a cross-sectional view illustrating the TFT substrate including the semiconductor layer 150, on which the source region 151, the drain region in 152, the low concentration doped region 153 and the channel region 154 are formed.

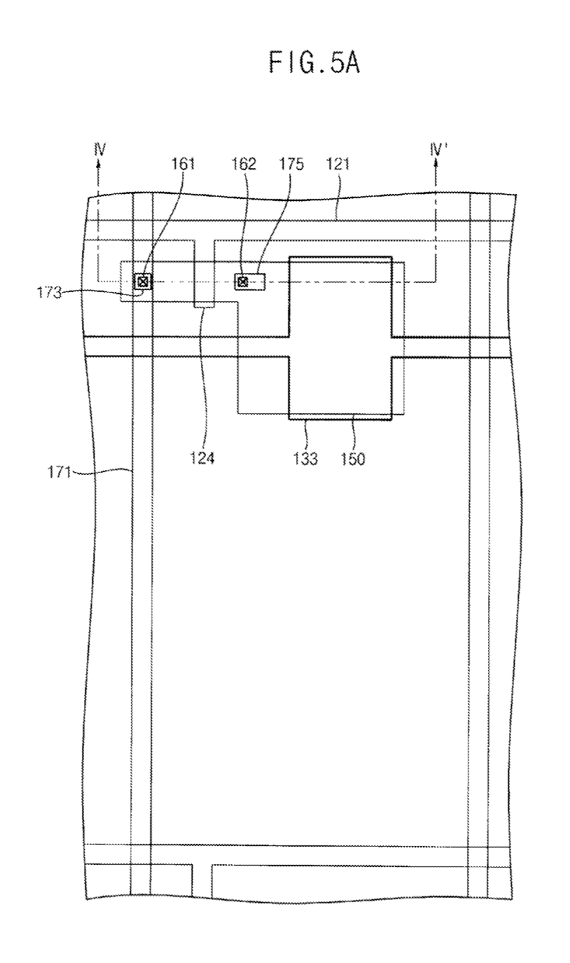

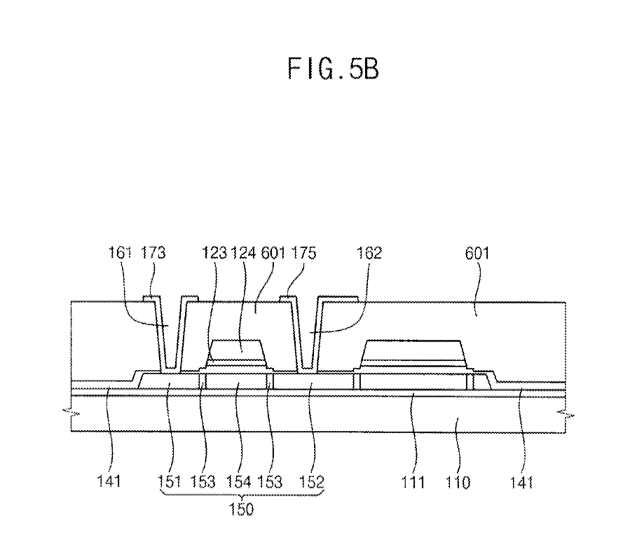

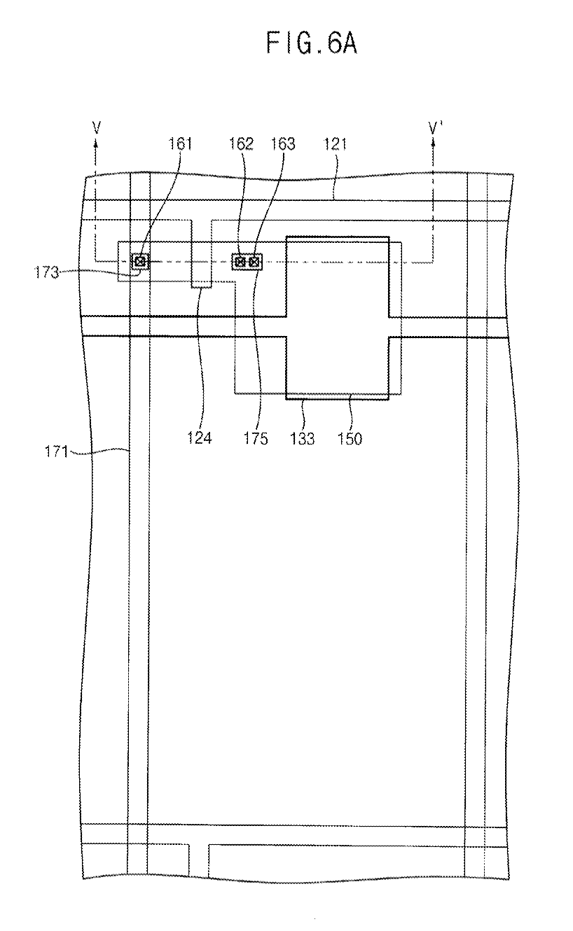

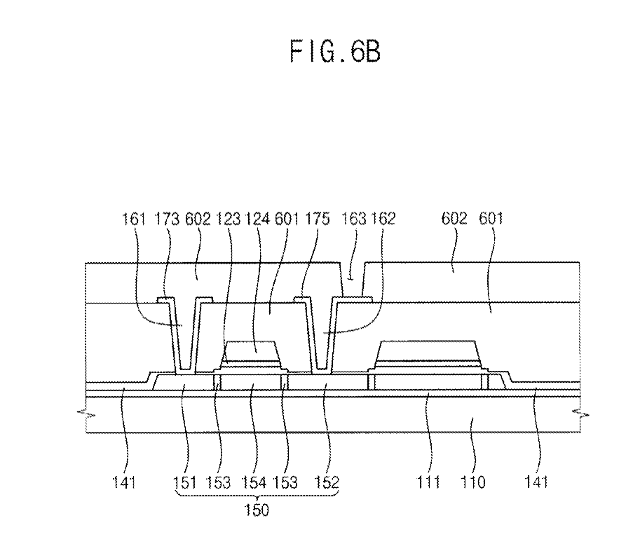

FIG. 5A is a plan view arranged according to a method for manufacturing the TFT substrate in FIG. 1. FIG. 5B is a cross-sectional view taken along a line IV-IV′ of FIG. 5A. FIG. 6A is a plan view arranged according to a method for manufacturing the TFT substrate in FIG. 1. FIG. 6B is a cross-sectional view taken along a line V-V of FIG. 6A.

Referring to FIGS. 5A and 5B, the first insulating interlayer 601 is formed on the gate insulating layer 141, the first and second gate electrodes 123 and 124. The first and second contact holes 161 and 162 are formed in the first insulating interlayer 601, for exposing the source and drain regions 151 and 152 of the semiconductor layer.

Then, the data line 171, the source electrode 173 and the drain electrode 175 are formed via the photolithography process, after depositing the data metal on the first insulating interlayer 601. The source and drain electrodes 173 and 175 are electrically connected to the source and drain regions 151 and 152 of the semiconductor layer 150 through the first and second contact holes 161 and 162, respectively.

Then, referring to FIGS. 6A and 68, the second insulating interlayer 602 is formed on the data line 171, the source electrode 173, the drain electrode 175 and the first insulating interlayer 601. The third contact hole 163 is formed in the second insulating interlayer 602, for exposing the drain electrode 175.

Then, the pixel electrode 190 is formed on the second insulating interlayer 602. The pixel electrode 190 is electrically connected to the drain electrode 175 through the third contact hole 163.

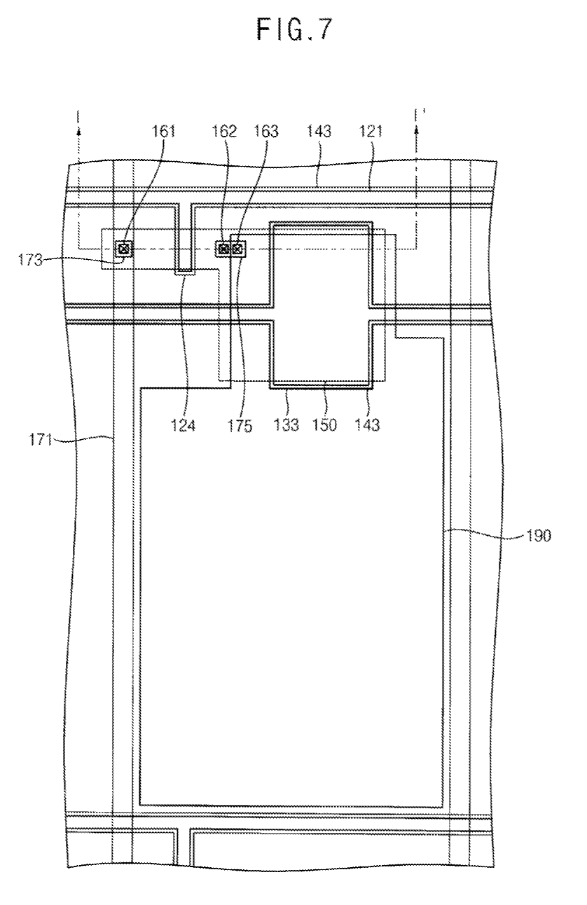

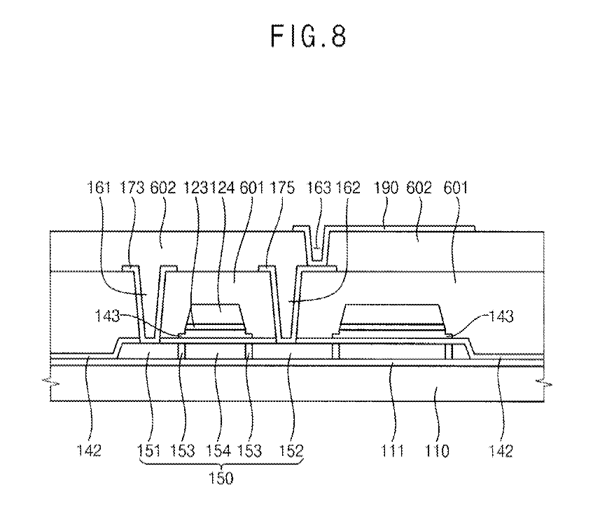

FIG. 7 is a plan view partially illustrating a TFT substrate according to another example embodiment of the present invention. FIG. 8 is a cross-sectional view taken along a line I-I′ of FIG. 7.

Referring to FIGS. 7 and 8, the TFT 110 substrate according to this example embodiment has a blocking layer 111 formed thereon. A source region 151, a drain region 152, a channel region 154 and a semiconductor layer 150 are formed on the blocking layer 111. The semiconductor layer 150 includes a low concentration doped region 153 formed between the source and channel regions and between the drain and channel regions.

A first gate insulating layer 142 and a second gate insulating layer 143 are formed on the semiconductor layer 150. In this case, the second gate insulating layer 143 is only formed on the low concentration doped region 153 and the channel region 154 of the semiconductor layer. A thickness of the second gate insulating layer 143 (a first region) formed on the low concentration doped region 153 is lower than that of the second gate insulating layer 143 (a second region) formed on the channel region 154.

The first gate insulating layer 142 includes silicon oxide (SiOx), and the second gate insulating layer 143 includes silicon nitride (SiNx).

Alternatively, the first gate insulating layer 142 may include silicon nitride (SiNx), and the second gate insulating layer 143 may include silicon oxide (SiOx).

A gate line 121, gate electrodes 123 and 124, a subsidiary capacity in electrode line 131 and a subsidiary capacity electrode 133 that include the same metal or alloy, are formed on the second gate insulating layer 143. The gate line 121, the gate electrodes 123 and 124, the subsidiary capacity electrode line 131 and the subsidiary capacity electrode 133 are formed from a double gate-metal layer.

For example, the first gate electrode 123 and the second gate electrode 124 are formed on the second gate insulating layer 143 overlapped with the channel region 154 of the semiconductor layer 150.

In this example embodiment, the first gate electrode 123 includes metal, such as titanium (Ti) or tantalum (Ta), or an alloy thereof, and the second gate electrode 124 includes at least one metal, such as molybdenum (Mo) and tungsten (W), or an alloy thereof.

Alternatively, the first gate electrode 123 may include at least one metal, such as molybdenum (Mo) and tungsten (W), or an alloy thereof, and the second gate electrode 124 may include metal, such as titanium (Ti) or tantalum (Ta), or an alloy thereof.

A first insulating interlayer 601 is formed on the first gate insulating layer 142, the second gate insulating layer 143, the first gate electrode 123 and the second gate electrode 124. The first insulating interlayer 601 may have a single-layer or multilayer structure having at least one of silicon oxide (SiOx) or silicon nitride (SiNx).

The first insulating interlayer 601 includes a first contact hole 161 and a second contact hole 162 exposing the source region 151 and the drain region 152 of the semiconductor layer 150

A data line 171, a source electrode 173 and a drain electrode 175 are formed on the first insulating interlayer 601.

In the TFT substrate according to this example embodiment, a portion of the data line is electrically connected to the source region 151 of the semiconductor layer 150 through the first contact hole 161, so that the portion of the data line is used for the source electrode 173 of the TFT. Alternatively, the data line 171 and the source electrode 173 may be separately formed from each other.

The drain electrode 175 is electrically connected to the drain region 152 of the semiconductor layer 150 through the second contact hole 162. The drain electrode 175 is separated from the source electrode 173 with respect to the channel region 154.

A second insulating interlayer 602 is formed on the data line 171, the source electrode 173 and the drain electrode 175. The second insulating interlayer 602 includes silicon oxide (SiOx) or silicon nitride (SiNx), and is used for a passivation layer that protects the TFT.

The second insulating interlayer 602 includes a third contact hole 163 for exposing the drain electrode 175.

A pixel electrode 190 is formed on the second insulating interlayer 602. The pixel electrode 190 is electrically connected to the drain electrode 175 through the third contact hole 163. The pixel electrode 190 may include indium tin oxide (ITO) or indium zinc oxide (IZO).

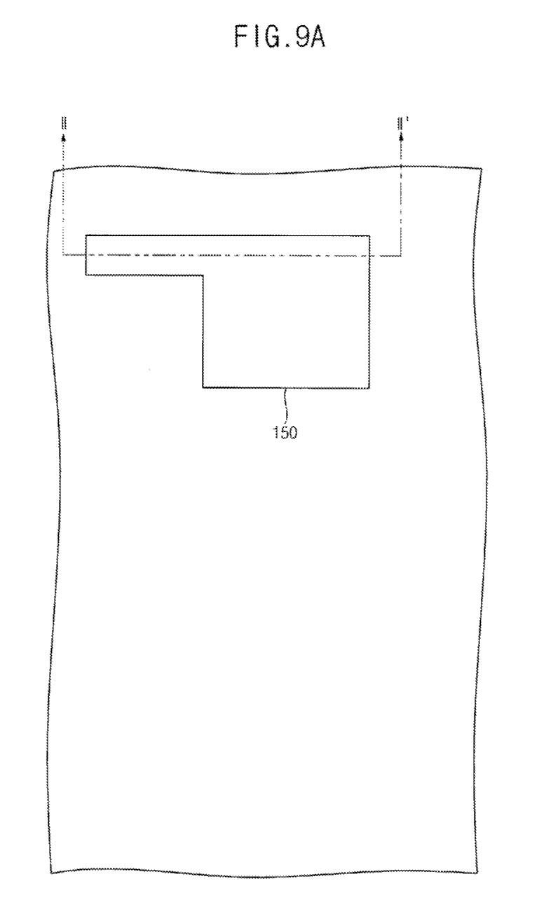

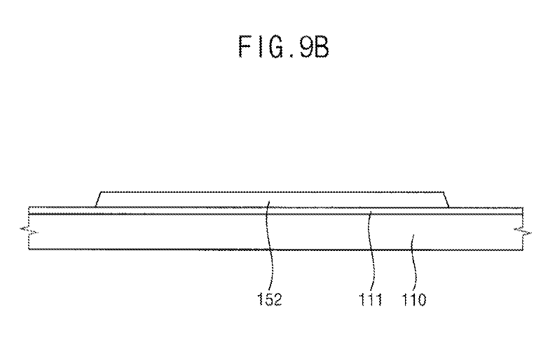

Referring to FIGS. 9A to 12B, a method for manufacturing the TFT substrate according to this example embodiment will be explained.

FIGS. 9A, 10A, 11A and 12A are plan views arranged according to a method for manufacturing the TFT substrate in FIG. 7. FIG. 9B is a cross-sectional view taken along a line II-II′ of FIG. 9A.

As illustrated in FIGS. 9A and 98, the blocking layer 111 is deposited on the TFT substrate 110. Then, the semiconductor layer 150 is deposited on the blocking layer 111. The semiconductor layer 15 includes amorphous silicon.

After depositing the semiconductor layer 150, the semiconductor layer 150 is crystallized by irradiating a laser beam or applying heat. The crystallized semiconductor layer 150 includes polycrystalline silicon. Then, the crystallized semiconductor layer 150 is patterned via a photolithography process, to be a predetermined shape.

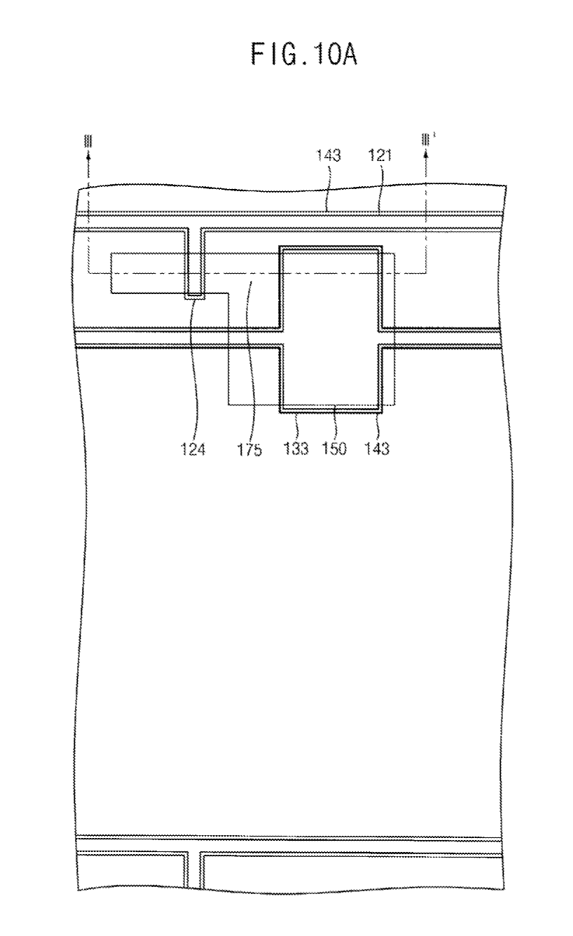

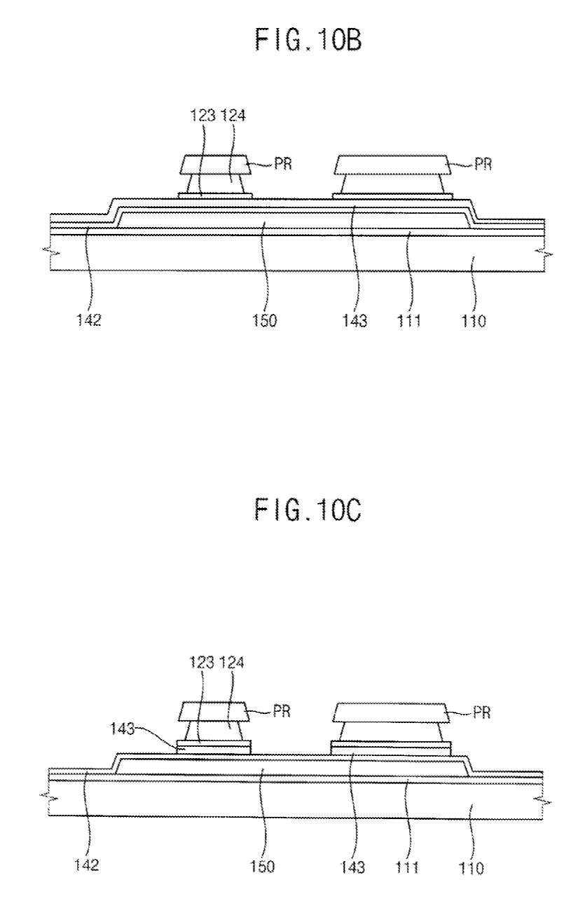

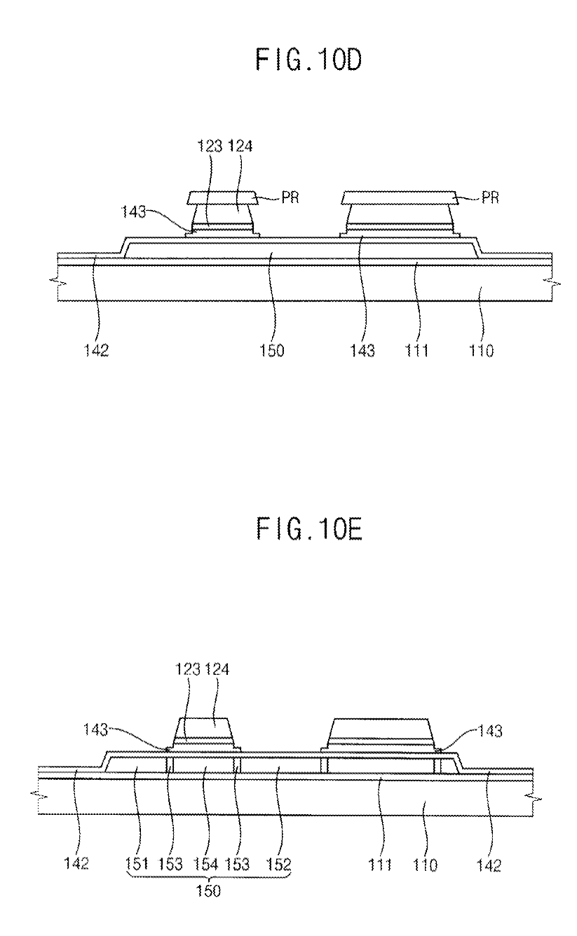

FIG. 10A is a plan view illustrating the TFT substrate after forming the first gate insulating layer 142, the second gate insulating layer 143 and the gate electrodes 123 and 124 on the crystallized semiconductor layer 150. In addition, FIGS. 10B to 10E are cross-sectional views taken along a line III-III′ of FIG. 10A, and are sequentially arranged according to manufacturing processes.

After patterning the semiconductor layer 150, the first gate insulating layer 142, the second gate insulating layer 143, the first gate metal 123 and the second gate metal 124 are sequentially deposited on the blocking layer 111 and the semiconductor layer 150. A photoresist film PR is coated on the second gate metal 124, and then, the photoresist film PR is patterned by irradiating light, such as UV light, using a mask.

Then, as illustrated in FIG. 10B, the first gate metal pattern 123 and the second gate metal 124 are formed via the photolithography process using the patterned photoresist film PR.

The photolithography process includes two alternative processes. The first process includes forming the second gate electrode 124 having a narrower width than that of the photoresist film PR by an isotropic etching process using the patterned photoresist film PR, then forming the first gate metal pattern 123 having substantially the same width as that of the patterned photoresist film PR by an anisotropic etching process. The second process includes forming the first gate metal pattern 123 and the second gate metal pattern 124 having substantially the same width as that of the photoresist film PR by the isotropic process using the patterned photoresist film PR, then forming the second gate electrode 124 having a narrower width than that of the photoresist film PR by the isotropic etching process.

In this case, the isotropic etching process may include a wet etching process using an etchant. A material may be etched both substantially perpendicular to the substrate and substantially parallel with the substrate in the isotropic etching process. Thus, the width of the second gate electrode 124 may be formed to be narrower than that of the photoresist film PR.

In addition, the anisotropic etching process may include a dry etching process using a gas having good reactivity. A material may be etched only substantially perpendicular to the substrate in the anisotropic etching process. A selective ratio according to the etched material in the anisotropic etching process is lower than that in the isotropic etching process. Thus, when the first gate metal pattern is patterned to have substantially the same width as that of the photoresist film, the gate insulating layer is partially etched.

FIG. 108 illustrates that the first gate metal pattern having substantially the same width as that of the patterned photoresist film is disposed under the second gate electrode having the narrower width than that of the patterned photoresist film. Alternatively, the second gate electrode having the narrower width than that of the patterned photoresist film may be disposed under the first gate metal pattern having substantially the same width than that of the patterned photoresist film.

After forming the first gate metal 123 and the second gate electrode 124, the second gate insulating layer 143 is patterned using the patterned photoresist film PR. The width of the second gate insulating layer 143 is substantially the same as that of the patterned photoresist film PR.

FIG. 10C is a cross-sectional view illustrating the TFT substrate after patterning the second gate electrode 124, the first gate metal pattern 123 and the second gate insulating layer 143. As mentioned above the width of the patterned photoresist film PR, the first gate metal pattern 123 and the second gate insulating layer 143 are substantially the same, but the width of the second gate electrode 124 is narrower than that of the photoresist film PR.

After patterning the second gate electrode 124, the first gate metal pattern 123 and the second gate insulating layer 143, the photoresist film PR is ashed to have substantially the same width as that of the second gate electrode 124.

Then, the first gate metal pattern 123 is etched using the ashed photoresist film PR, so that the first gate electrode 123 is formed to have substantially the same width as that of the second gate electrode 124. The first gate electrode 123 is formed via the anisotropic etching process. Since the anisotropic etching process has the characteristics mentioned above, the second gate insulating layer includes a stepped portion. For example, the thickness of the gate insulating layer (the first region), in which the low concentration doped region is formed, is thinner than that of the gate insulating layer (the second region) formed under the first gate electrode 123 and the second gate electrode 124.

FIG. 10D is a cross-sectional view illustrating the TFT substrate, after forming the first gate electrode 123 and the second gate electrode 124 using the photoresist film PR shaved by the etching process.

After forming the first and second gate electrodes 123 and 124, the ashed photoresist film PR is removed. Then, the source region 151 and the drain region 152 doped with dopants at a high concentration, and the low concentration doped region 153 doped with the dopants at a low concentration are simultaneously formed, using the first and second gate electrodes 123 and 124, and the second gate insulating layer.

For example, when the semiconductor layer 150 is doped with the dopants having substantially the same kinetic energy, the semiconductor layer, on which the second gate insulating layer 142 is not formed, is doped with the dopants at a high concentration, and the semiconductor layer, on which the second gate insulating layer 142 is formed, is doped with the dopants at a low concentration.

The semiconductor layer that is not doped with the dopants and on which the first and second gate electrodes 123 and 124 are formed, includes the channel region 154 of the TFT.

FIG. 10E is a cross-sectional view illustrating the TFT substrate including the semiconductor layer 150 in which the source region 151, the drain region 152, low concentration doped region 153 and the channel region 154 is formed.

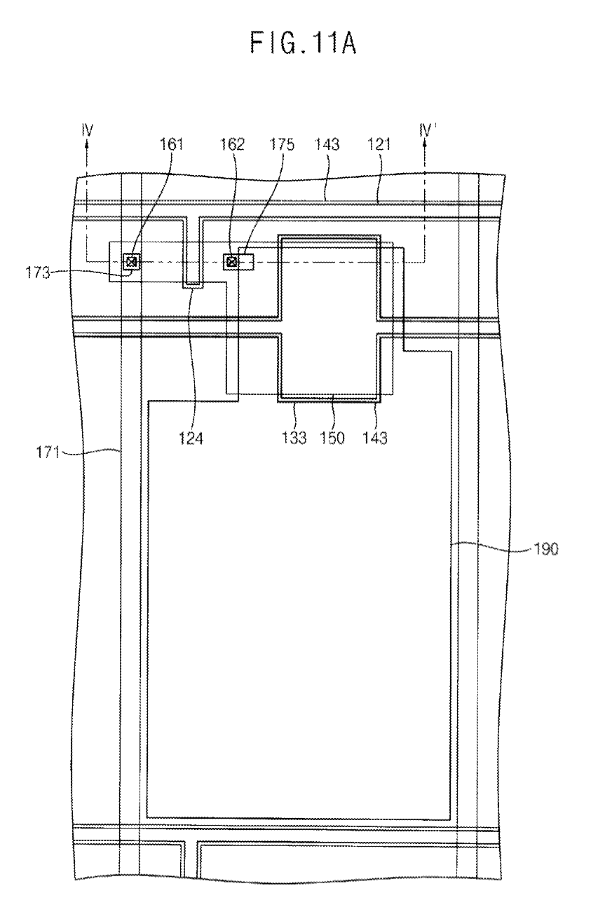

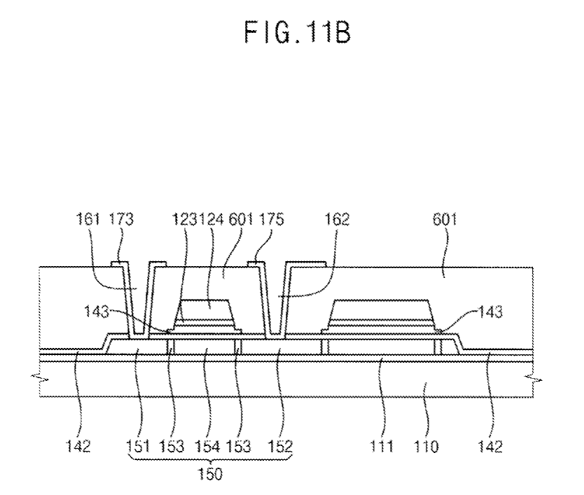

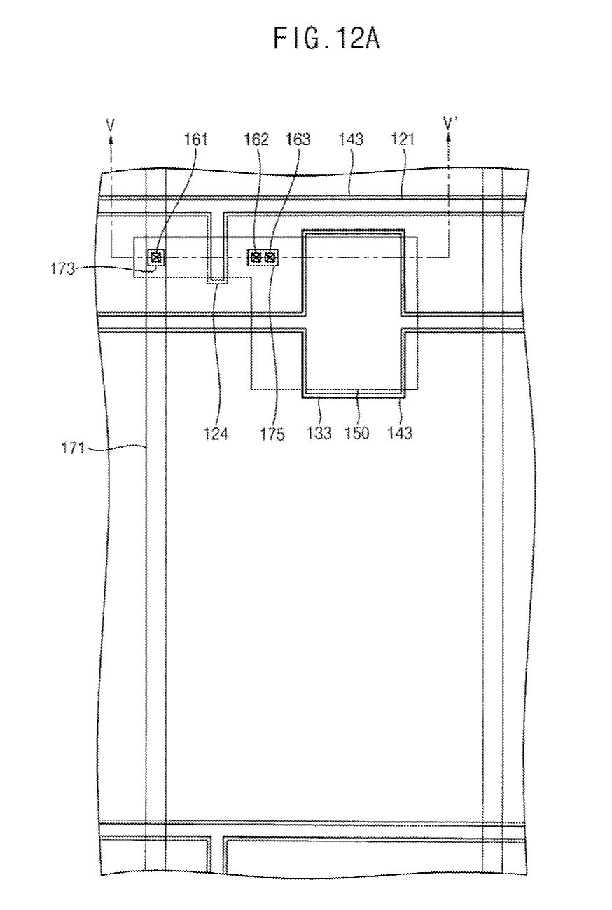

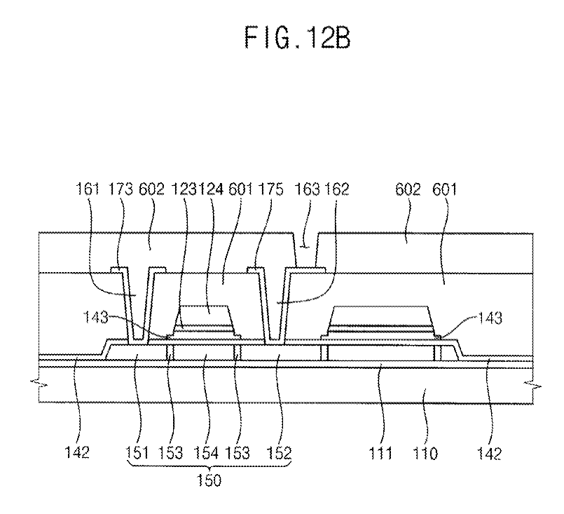

FIGS. 11A and 12A are plan views arranged according to a method for manufacturing the TFT substrate in FIG. 7. FIG. 11B is a cross-sectional view taken along a line IV-IV′ of FIG. 11A. FIG. 12B is a cross-sectional view taken along a line V-V′ of FIG. 12A.

Then, as illustrated in FIGS. 11A and 111B the first insulating interlayer 601 is formed on the second gate insulating layer 143, the first gate electrode 123 and the second gate electrode 124.

The first and second contact holes 161 and 162 are formed on the first insulating interlayer 601 for exposing the source region 151 and the drain region 152 of the semiconductor layer 150.

Then, after depositing a data metal on the first insulating interlayer 601, in the data line 171, the source electrode 173 and the drain electrode 175 are formed via the photolithography process. The source electrode 173 and the drain electrode 175 are electrically connected to the source region 151 and the drain region 152 of the semiconductor layer 150 through the first contact hole 161 and the second contact hole 162, respectively.

Then, as illustrated in FIGS. 12A and 12B, the second insulating interlayer 602 is formed on the data line 171, the source electrode 173, the drain electrode 175 and the first insulating interlayer 601. The third contact hole 163 is formed in the second insulating interlayer 602, for exposing the drain electrode 175.

Then, the pixel electrode 190 is formed on the second insulating interlayer 602. The pixel electrode 190 is electrically connected to the drain electrode 175 through the third contact hole 163.

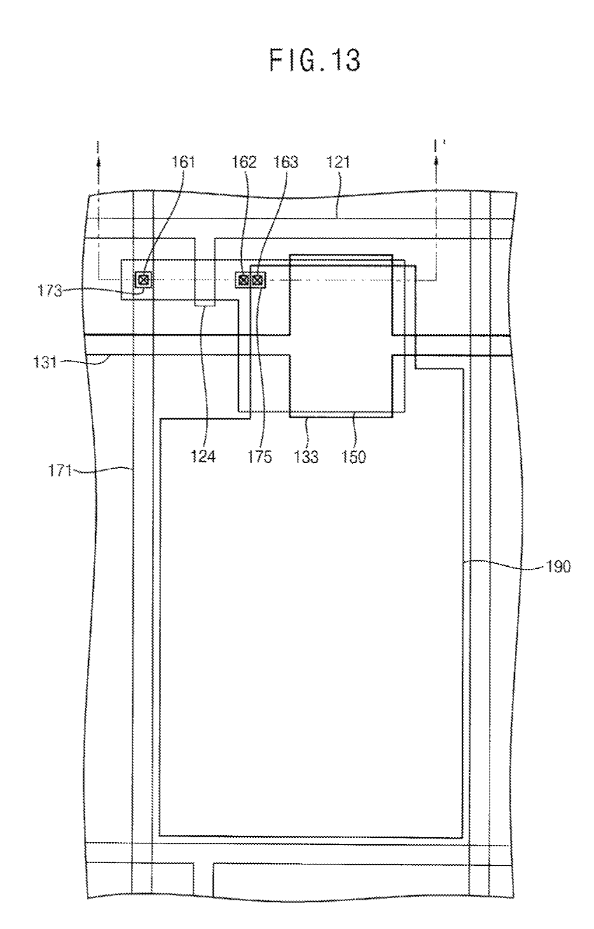

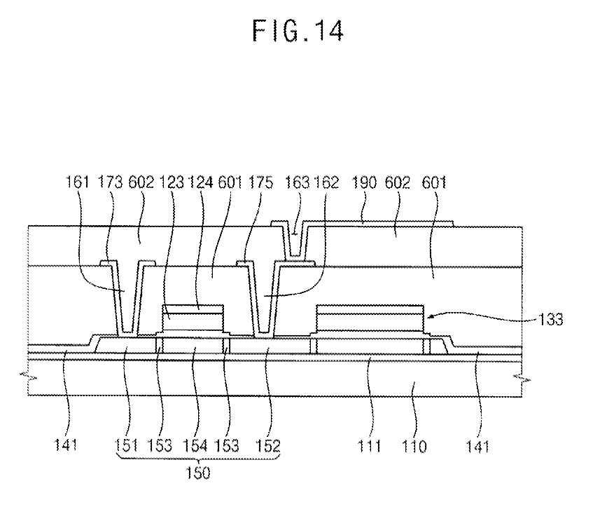

FIG. 13 is a plan view illustrating a portion of a TFT substrate according to another example embodiment of the present invention. FIG. 14 is a cross-sectional view taken along a line I-I′ of FIG. 13.

Referring to FIGS. 13 and 14, the TFT substrate according to this example embodiment will be explained.

Referring to FIG. 13, the TFT substrate includes a TFT formed in a crossing portion between a gate line 121 transferring a driving signal and a data line 171 transferring an image signal.

The TFT includes a semiconductor layer 150, a gate electrode, a source electrode 173 and a drain electrode 175. The semiconductor layer includes polycrystalline silicon. The gate electrode is protruded from the gate line 121 and is overlapped with the semiconductor layer 150. The source and drain electrodes 173 and 175 are electrically connected to the semiconductor layer 150 through a first contact hole 161 and a second contact hole 162, respectively.

In the TFT substrate according to the example embodiment, a portion of the data line 171 includes the source electrode 173 of the TFT. Alternatively, the source electrode 173 may be separated from the data line 171.

The drain electrode 175 of the TFT is electrically connected to a pixel electrode 190 through a third contact hole 163. The pixel electrode 190 may include indium tin oxide (ITO) or indium zinc oxide (IZO).

The TFT substrate according to the example embodiment further includes a storage line 131 that is formed along the gate line 121. A storage electrode 133 electrically connected to the storage line 131 is overlapped with the pixel electrode 190, to form a storage capacitor.

Referring to FIG. 14, in the TFT substrate according to the example embodiment, a blocking layer 111 including silicon oxide (SiOx) or silicon nitride (SiNx) is formed on a transparent base substrate 110. The semiconductor layer 150 is formed on the blocking layer. The semiconductor layer includes a source region 151, a drain region 152 and a channel region 154. The source and drain regions 151 and 152 are doped with n-type or p-type dopants at a high concentration. The channel region 154 is disposed between the source and it drain regions 151 and 152. In this case, the semiconductor layer 154 includes polycrystalline silicon. A low concentration doped region 153 doped with conductive dopants at a low concentration is formed between the source and channel regions 151 and 154, and between the drain and channel regions 152 and 154.

A gate insulating layer 141 is formed on the semiconductor layer 150. The gate insulating layer 141 may include silicon oxide (SiOx) or silicon nitride (SiNx). The gate insulating layer 141 includes a first region formed on the source and drain regions 151 and 152 of the semiconductor layer 150, a second region formed on the channel region 154, and a third region formed on the low concentration doped region 153. The thickness of the gate insulating layer in the first region is thinner than that of the gate insulating layer in the second region, and the thickness of the gate insulating layer in the third region is thinner than that of the gate insulating layer in the second region. In addition, the thickness of the gate insulating layer in the first region is thinner than that of the gate insulating layer in the third region. The thickness difference in each region is due to the number of dry etching processes applied to each region. For example, the first region is etched twice via the dry etching process, the third region is etched once via the dry etching process, and the second region is not etched, and thus thickness is different in each region.

The gate line 121, the gate electrode and the storage electrode 133 are formed on the gate insulating layer 141. The gate line 121, the gate electrode and the storage electrode 133 include a double-metal layer.

The gate electrode is overlapped with the channel region 154 of the semiconductor layer 150, and includes a first gate electrode 123 and a second gate electrode 124.

In this case, the first gate electrode 123 includes metal including at least one of molybdenum (Mo) and tungsten (W) having a low resistivity, or an alloy thereof. The second gate electrode 124 includes metal including titanium (Ti) or tantalum (Ta) having a good adhesive strength with a photoresist film PR, or an alloy thereof. In this case, a lifting of the photoresist film PR may be prevented due to the strong adhesive strength between the second gate electrode 124 and the photoresist film PR, so that the gate electrode may be etched to have a predetermined shape.

A first insulating interlayer 601 is formed on the gate line 121, the second gate electrode 124 the storage electrode 133 and the storage line 131. The first insulating interlayer 601 includes the first contact hole 161 and the second contact hole 162 for exposing the source and drain regions 151 and 152 of the semiconductor layer 150. The first insulating interlayer 601 may have a single-layer or multilayer structure having silicon nitride (SiNx) or silicon oxide (SiOx).

The data line 171 is formed on the first insulating interlayer 601. The data line 171 crosses the gate line 121 and the data and the gate lines 171 and 121 defines a pixel area. The data line 171 is partially connected to the source region 151 through the first contact hole 161, A portion of the data line 171 connected to the source region 151 is used for the source electrode 173 of the TFT.

The drain electrode 175 is formed from the same layer as the data line 171, and is separated from the source electrode 173. The drain electrode 175 is electrically connected to the drain region 152 through the second contact hole 162.

The drain electrode 175 and the data line 171 may include a conductive layer having aluminum based metal such as aluminum (Al) or aluminum alloy, like the gate line. In addition to the conductive layer the drain electrode 175 and the data line 171 may have a multilayer structure having metal, such as chromium (Cr), titanium (Ti), tantalum (Ta) and molybdenum (Mo) that have good physical, chemical and electrical characteristics with indium tin oxide (ITO) or indium zinc oxide (IZO), or an alloy thereof.

A second insulating interlayer 602 is formed on the entire surface of the first insulating interlayer 601 on which the drain electrode 175 and the data line 171 are formed. The second insulating interlayer 602 includes the third contact hole 163 for exposing the drain electrode 175. The second insulating interlayer 602 includes silicon oxide (SiOx) or silicon nitride (SiNx), and protects the TFT.

The pixel electrode 190, which is connected to the drain electrode 175, is formed on the second insulating interlayer 602. The pixel electrode 190 may include indium tin oxide (ITO) or indium zinc oxide (IZO).

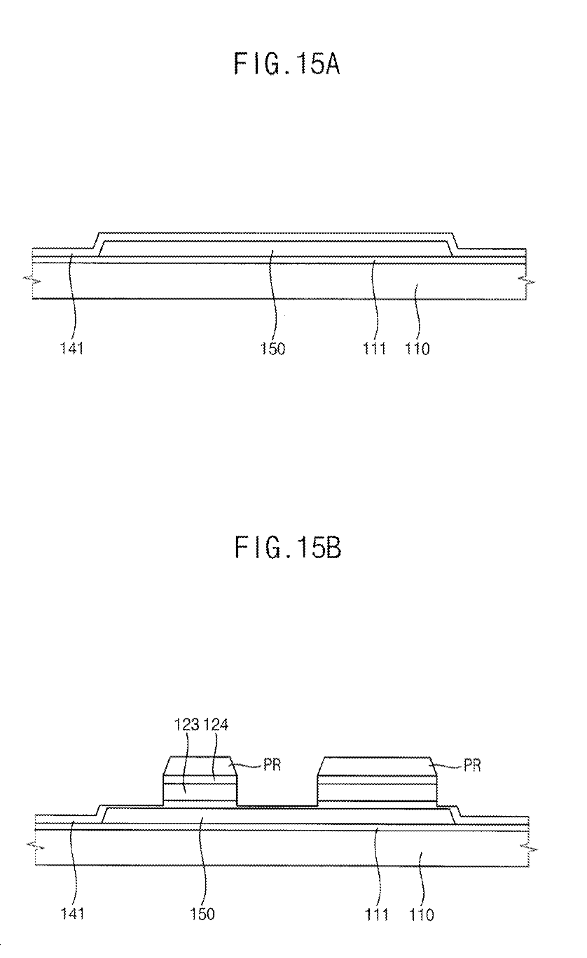

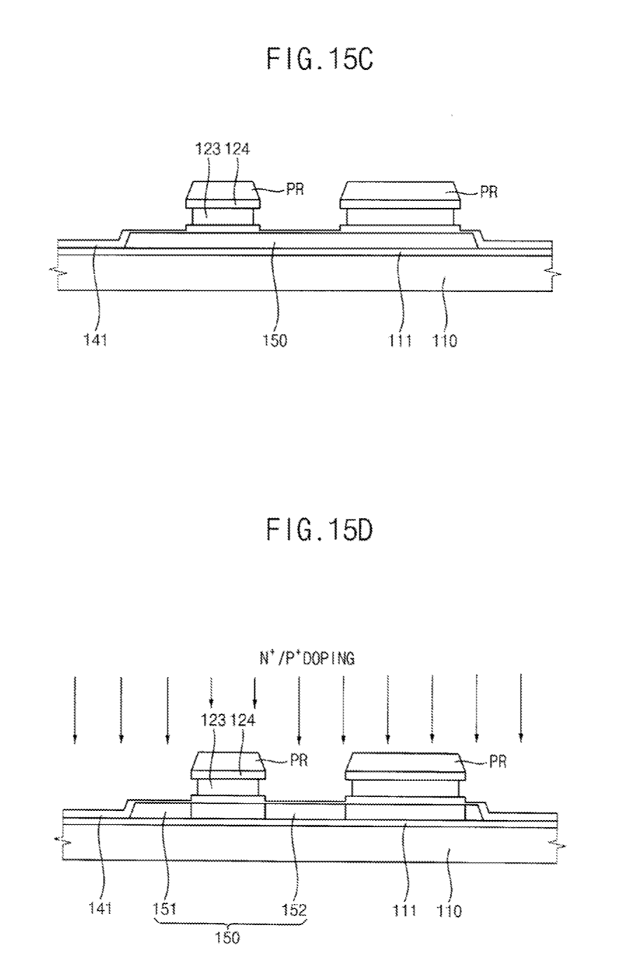

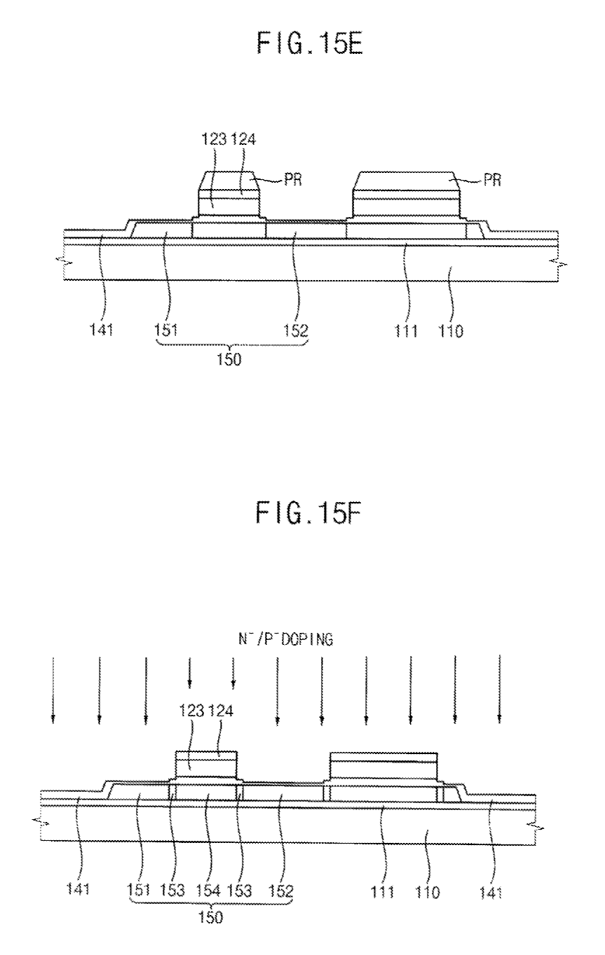

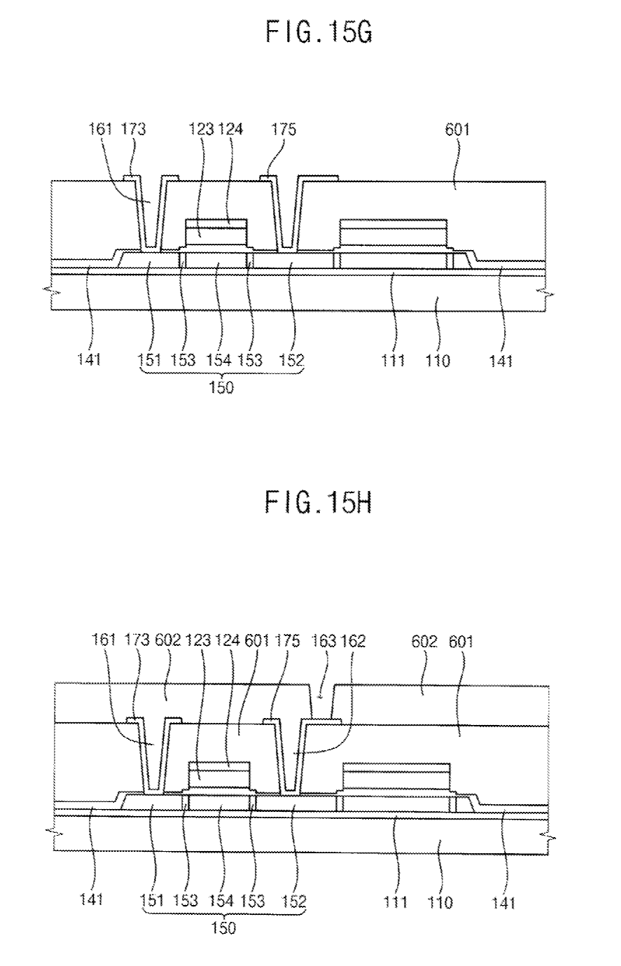

FIGS. 15A to 15H are cross-sectional views illustrating a method for manufacturing the TFT substrate according to the embodiment illustrated in FIG. 13.

Referring to FIGS. 15A to 18B, the method for manufacturing the TFT substrate according to the embodiment illustrated in FIG. 12 will be explained.

FIG. 15A is a cross-sectional view illustrating a process of forming the blocking layer, the semiconductor layer and the gate insulating layer on the base substrate 110.

Referring to FIG. 15A, the blocking layer 111 is formed on the entire surface of the base substrate 110, and the semiconductor layer 150 including amorphous silicon is formed on the blocking layer 111.

Then, a laser beam is irradiated onto the semiconductor layer 150 including amorphous silicon, so that the semiconductor layer 150 is formed to have polycrystalline silicon and to have a predetermined shape.

Then, the gate insulating layer 141 is formed on the blocking layer 111, for covering the patterned semiconductor layer 150.

FIG. 15B is a cross-sectional view illustrating a process of forming the first and second gate electrodes on the base substrate.

Referring to FIG. 15B, a first gate metal layer and a second gate metal layer are sequentially deposited on the gate insulating layer 141. The first gate metal layer includes at least one of molybdenum (Mo) and tungsten (W). The second gate metal layer includes one of titanium (Ti) and tantalum (Ta).

Then, the photoresist film PR is coated on the second gate metal layer, and light, such as UV light, is irradiated onto the photoresist film PR using a mask to pattern the photoresist film PR.

Then, the first and second gate electrodes 123 and 124 are formed by patterning the first and second gate metal layers via a photolithography process using the patterned photoresist film PR. The above-mentioned process preferably includes an anisotropic etching process. When the first and second gate metal layers are partially etched by the anisotropic etching process, the gate insulating layer 141 is partially etched. Thus, the thickness of a portion of the gate insulating layer 141 that is not overlapped with the photoresist film PR is reduced.

FIG. 15C is a cross-sectional view illustrating a process of reducing width of the first gate electrode.

Referring to FIG. 150, the width of the first gate electrode 123 is selectively reduced via an isotropic etching process using the patterned photoresist film PR. To etch the first gate electrode 123 selectively, an etchant that has an etching selective ratio of the first gate electrode 123 higher than that of the second gate electrode 124 is used. According as the width of the first gate electrode 123 is reduced, the width of the first gate electrode 123 becomes narrower than that of the patterned photoresist film PR or that of the second gate electrode 124.

In the example embodiment, the first and second gate electrodes 123 and 124 are formed to have substantially the same width as that of the photoresist film PR by the anisotropic etching process using the patterned photoresist film PR, and then the first gate electrode 123 is formed to have narrower width than that of the photoresist film PR by the isotropic etching process. Alternatively, the first gate electrode 123 may be formed to have narrower width than that of the photoresist film PR by the isotropic etching process, and then the second gate electrode 124 may be formed to have substantially the same width as that of the photoresist film PR by the anisotropic etching process.

The isotropic etching process may include a wet etch using the etchant, and the anisotropic etching process may include a dry etch using a gas having a good reactivity.

In FIG. 15D is a cross-sectional view illustrating a process of forming the source and drain regions by doping the semiconductor layer with dopants.

Referring to FIG. 5D, the semiconductor layer is doped with the dopants at a high concentration using the patterned photoresist film PR as a doping mask, so that the source and drain regions 151 and 152 are formed in the semiconductor layer 150. In this case, the dopants include an n-type dopant ion when a carrier of the TFT is an electron. The dopants include a p-type dopant ion when the carrier of the TFT is a hole.

FIG. 15E is a cross-sectional view illustrating a process of reducing the width of the second gate electrode after an ashing process on the photoresist film.

Referring to FIG. 15E, the photoresist film PR is ashed. Ashing is a process that shaves the photoresist film PR using a mixed gas of oxygen (O₂) and carbon tetrafluoride (CF₄). The photoresist film PR is formed to have substantially the same width as that of the first gate electrode 123 via the ashing process.

Then, the second gate electrode 124 is partially etched using the ashed photoresist film PR, so that the second gate electrode 124 having substantially the same width as that of the first gate electrode 123 is formed. For example, the above etching process includes the anisotropic etching process.

FIG. 15F is a cross-sectional view illustrating a process of doping the dopants on the semiconductor layer to form the low concentration doped region.

Referring to FIG. 15F, the ashed photoresist film PR is completely removed. Then, the semiconductor layer 150 is partially doped with the dopants at a low concentration using the first and second gate electrodes 123 and 124 as the doping mask, to form the low concentration doped region 153. In this case, the dopants include the same type of ion as that of the source and drain regions 151 and 152.

The semiconductor layer that is not doped with the dopants and is disposed under the first gate electrode 123 includes the channel region 154 of the TFT. Thus, the low concentration doped region 153 is formed between the source and channel regions 151 and 154, and between the drain and channel regions 152 and 154.

FIG. 15G is a cross-sectional view illustrating a process of forming the first insulating interlayer, the source electrode and the drain electrode.

Referring to FIG. 15G, the first insulating interlayer 601 is formed on the gate insulating layer 141 to cover the first and second gate electrodes 123 and 124, then the first and second contact holes 161 and 162 are formed in the first insulating interlayer 601 for partially exposing the source and drain regions 151 and 152.

. Then, after depositing the data metal layer on the first insulating interlayer 601, the data line 171, the source electrode 173 and the drain electrode 175 are formed via the photolithography process. The source and drain electrodes 173 and 175 are electrically connected to the source and drain regions 151 and 152 of the semiconductor layer 150 through the first and second contact holes 161 and 162, respectively.

FIG. 15H is a cross-sectional view illustrating a process of forming the second insulating interlayer.

Referring to FIGS. 15H and 14, the second insulating interlayer 602 is formed on the first insulating interlayer 601 to cover the data line 171, the source electrode 173 and the drain electrode 175, and then, the third contact hole 163 is formed in the second insulating interlayer 602 for partially exposing the drain electrode 175.

Then, the pixel electrode 190 is formed on the second insulating interlayer 602. The pixel electrode 190 is electrically connected to the drain electrode 175 through the third contact hole 163.

In this example embodiment, a stepped portion is formed in the gate insulating layer 141 via the above-mentioned two anisotropic etching processes. For example, the thickness of the first region, in which the gate insulating layer 141 formed on the source and drain regions 151 and 152 is formed, is thinner than that of the third region in which the gate insulating layer 141 formed on the low concentration doped region 154 is formed. In addition, the thickness of the in third region is thinner than that of the second region in which the gate insulating layer 141 formed under the first gate electrode 123 is formed.

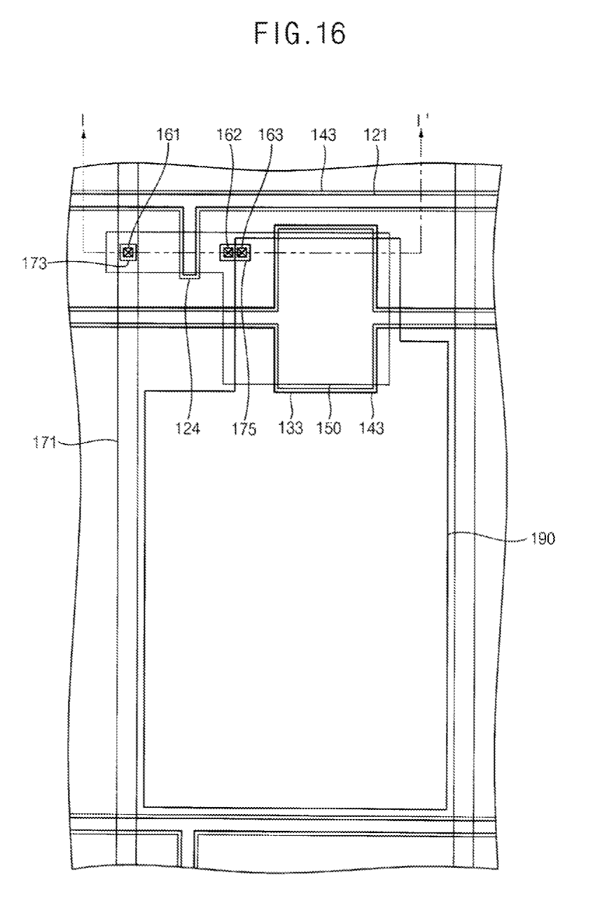

Referring to FIGS. 16 to 18E, a TFT substrate and a method for manufacturing the TFT substrate according to another example embodiment will be explained.

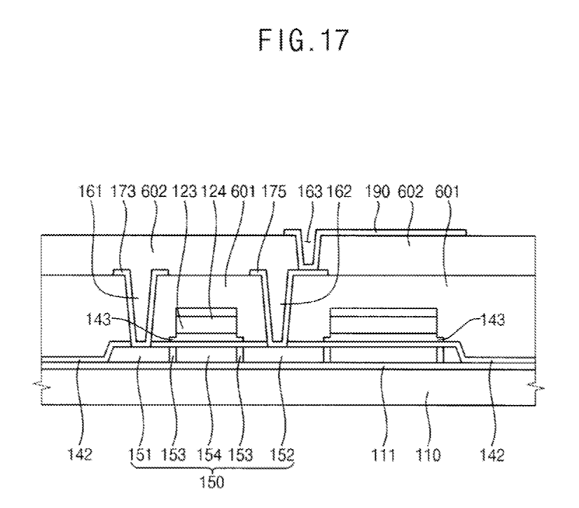

FIG. 16 is a plan view illustrating a portion of the TFT substrate according to another example embodiment of the present invention. FIG. 17 is a cross-sectional view taken along a line I-I′ of FIG. 16.

Referring to FIGS. 16 and 17, in the TFT substrate according to the example embodiment, a blocking layer 111 is formed on a substrate 110, and a semiconductor layer 150 is formed on the blocking layer 111. The semiconductor layer 150 includes a source region 151, a drain region 152, a channel region 154 and a low concentration doped region 153, and includes polycrystalline silicon. In this case, the low concentration doped region 153 is formed between the source region 151 and the channel region 154, and between the drain region 152 and the channel region 154.

A first gate insulating layer 142 and a second gate insulating layer 143 are formed on the semiconductor layer 150. In this case, the second gate insulating layer 143 is formed only on the low concentration doped region 153 and the channel region 154 of the semiconductor layer 150. A thickness of a first region, in which the second gate insulating layer 143 formed on the low concentration doped region 153 is formed, is thinner than that of a second region in which the second gate insulating layer 143 formed on the channel region 154 is formed.

The first gate insulating layer 142 includes silicon oxide (SiOx), and the second gate insulating layer 143 includes silicon nitride (SiNx). Alternatively, the first gate insulating layer 142 may include silicon nitride (SiNx), and the second gate insulating layer 143 may include silicon oxide (SiOx).

A gate line 121, a gate electrode, a storage line 131 and a storage electrode 133 that include the same metal or alloy, are formed on the second gate insulating layer 143. In this case, the gate line 121, the gate electrode, the storage line 131 and the storage electrode 133 includes a double-metal layer.

For example, a first gate electrode 123 and a second gate electrode 124 are formed on the second gate insulating layer 143 overlapped with the channel region 154 of the semiconductor layer 150. In the example embodiment, the first gate electrode 123 includes metal including at least one of molybdenum (Mo) and tungsten (W), or an alloy thereof. The second gate electrode 124 includes metal including titanium (Ti) or tantalum (Ta), or an alloy thereof.

A first insulating interlayer 601 is formed on the first gate insulating layer 142 to cover the first and second gate electrodes 123 and 124, and the second gate insulating layer 143. The first insulating interlayer 601 may have a single-layer or multilayer structure including at least one of silicon oxide (SiOx) or silicon nitride (SiNx). The first insulating interlayer 601 includes a first contact hole 161 and a second contact hole 162 for exposing the source region 151 and the drain region 152 of the semiconductor layer 150.

The data line 171, the source electrode 173 and the drain electrode 175 are formed on the first insulating interlayer 601. The drain electrode 175 is in electrically connected to the drain region 152 of the semiconductor layer 150 through the second contact hole 162. The source electrode 173 is separated from the drain electrode 175 with respect to the channel region 154, and is electrically connected to the source region 151 of the semiconductor layer 150 through the first contact hole 161.

A second insulating interlayer 602 is formed on the first insulating interlayer 601 to cover the data line 171, the source electrode 173 and the drain electrode 175. The second insulating interlayer 602 includes silicon oxide (SiOx) or silicon nitride (SiNx), and protects the TFT. The second insulating interlayer 602 includes a third contact hole 163 for exposing the drain electrode 175.

A pixel electrode 190 is formed on the second insulating interlayer 602, and is electrically connected to the drain electrode 175 through the third contact hole 163.

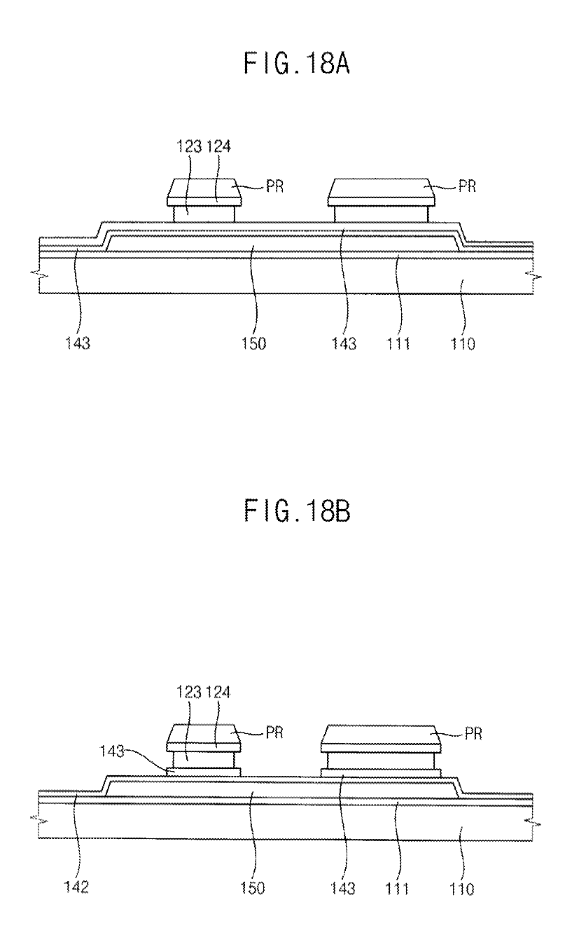

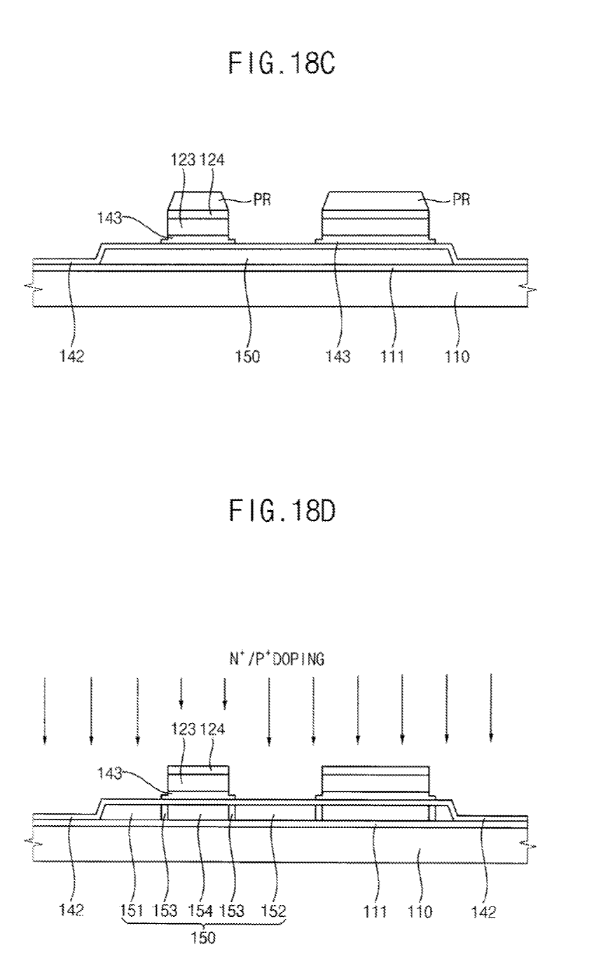

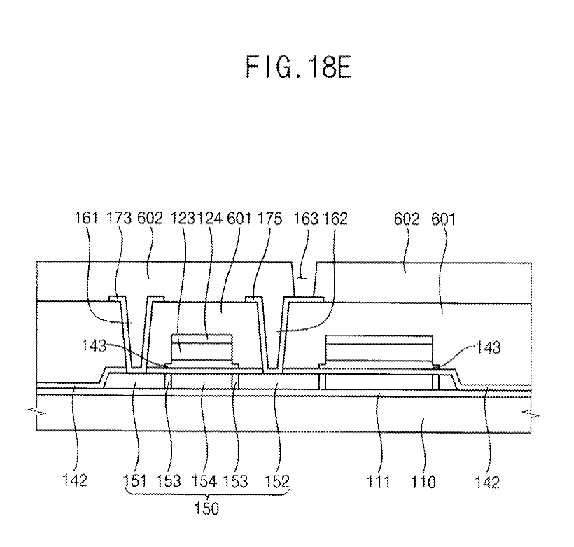

FIGS. 18A to 18E are cross-sectional views illustrating a method for manufacturing the TFT substrate according to the embodiment of the invention illustrated in FIG. 16.

FIG. 18A is a cross-sectional view illustrating a process of forming the semiconductor layer, the first and second gate insulating layers, and the first and second gate electrodes.

Referring to FIG. 18A, the blocking layer 111 is deposited on the substrate 110, and the semiconductor layer 150 including amorphous silicon is deposited. Then, a laser beam is irradiated onto the semiconductor layer 150, to transform the amorphous silicon into polycrystalline silicon. The crystallized semiconductor layer 150 is patterned to have a predetermined shape via a photolithography process.

Then, the first and second gate insulating layers 142 and 143 are deposited on the blocking layer 111 to cover the semiconductor layer 150, and first and second gate metal layers are sequentially deposited. A photoresist film PR is coated on the second gate metal layer, and then the photoresist film PR is patterned.

Then, the first and second gate electrodes 123 and 124 are formed via the photolithography process using the patterned photoresist film PR. The width of the first gate electrode 123 is narrower than that of the second gate electrode 124 via an isotropic etching process and an anisotropic etching process.

FIG. 18B is a cross-sectional view illustrating a process of etching the second gate insulating layer.

Referring to FIG. 18B, the second gate insulating layer 143 is patterned using the patterned photoresist film PR. The width of the patterned second gate insulating layer 143 is substantially the same as that of the patterned photoresist film PR.

FIG. 18C is a cross-sectional view illustrating a process of reducing the width of the second gate electrode.

Referring to FIG. 18C, the photoresist film PR is ashed to have substantially the same width as that of the first gate electrode 123.

Then, the second gate electrode 124 is partially etched using the ashed in photoresist film PR, so that the width of the second gate electrode 124 is reduced to be substantially the same as that of the first gate electrode 123. Since the etching process includes the anisotropic etching process, the second gate insulating layer 143 includes a stepped portion. For example, the thickness of the first region, in which the second gate insulating layer 143 formed on the low concentration doped region 153 is formed, is thinner than that of the second region in which the second gate insulating layer 143 formed under the first gate electrode 123 is formed.

FIG. 18D is a cross-sectional view illustrating a process of doping dopants on the semiconductor layer.

Referring to FIG. 18D, after removing the ashed photoresist film PR, the semiconductor layer 150 is doped with the dopants at a high concentration using the first and second gate electrodes 123 and 124, and the second gate insulating layer 143. Then, the source and drain regions 151 and 152 doped with the dopants at a high concentration, and the low concentration doped region 153 doped with the dopants at a low concentration, are simultaneously formed on the semiconductor layer 150.

For example, when the semiconductor layer 150 is doped with the dopants having substantially the same kinetic energy the semiconductor layer, on which the second gate insulating layer 142 is not formed, is doped with the dopants at a high concentration, and the semiconductor layer, on which the second gate insulating layer 142 is formed, is doped with the dopants at a low concentration. The semiconductor layer that is not doped with the dopants and on which the first in gate electrode 123 are formed, includes the channel region 154 of the TFT.

FIG. 18E is a cross-sectional view illustrating a process of forming the first and second insulating interlayers and so on.

Referring to FIGS. 18E and 17, the first insulating interlayer 601 is formed on the first gate insulating layer 142 to cover the first and second gate electrodes 123 and 124, and the second gate insulating layer 143, and then, the first and second contact holes 161 and 162 are formed in the first insulating interlayer 601 for partially exposing the source and drain regions 151 and 152 of the semiconductor layer 150.

Then, the data metal layer is deposited on the first insulating interlayer 601, and the data line 171, the source electrode 173 and the drain electrode 175 are formed via the photolithography process. The source and drain electrodes 173 and 175 are electrically connected to the source and drain regions 151 and 152 of the semiconductor layer 150 through the first and second contact holes 161 and 162, respectively.

Then, the second insulating interlayer 602 is formed on the first insulating interlayer 601 to cover the data line 171, the source electrode 173 and the drain electrode 175, and then, the third contact hole 163 is formed in the second insulating interlayer 602 for partially exposing the drain electrode 175.

Finally, the pixel electrode 190 is formed on the second insulating interlayer 602. The pixel electrode 190 is electrically connected to the drain electrode 175 through the third contact hole 163.

According to exemplary embodiments of the invention the source region, the drain region, the channel region and the tow concentration doped region may be uniformly formed in each TFT, so that the TFT substrate having the uniform TFT may be manufactured.

Having described the example embodiments of the present invention and its advantage, it is noted that various changes substitutions and alterations can be made herein without departing from the spirit and scope of the invention as defined by appended claims.

What is claimed is:

1. A thin-film transistor (TFT) substrate comprising:
a base substrate;
a semiconductor layer being formed on the base substrate and including a source region, a drain region, a channel region and a low concentration doped region, the channel region formed between the source and drain regions, the low concentration doped region formed both between the source and channel regions and between the drain and channel regions;
in a gate insulating layer formed on the semiconductor layer;
a first gate electrode formed on the gate insulating layer to be overlapped with the channel region; and
a second gate electrode formed on the first gate electrode,
wherein the gate insulating layer includes a first region formed in the source and drain regions and a second region formed in the channel region, and a thickness of the first region is thinner than that of the second region.

2. The TFT substrate of claim 1, wherein the gate insulating layer further comprises a third region formed in the low concentration doped region,
the first region is thinner than the third region,
and the third region is thinner than the second region.

3. The TFT substrate of claim 1, wherein the first gate electrode comprises at least one of titanium (Ti) and tantalum (Ta).

4. The TFT substrate of claim 1, wherein the second gate electrode comprises at least one of molybdenum (Mo) and tungsten (W).

5. The TFT substrate of claim 1, wherein the gate insulating layer comprises at least one of silicon oxide (SiOx) and silicon nitride (SiNx).

6. A TFT substrate comprising:
a base substrate;
a semiconductor layer being formed on the base substrate and including a source region, a drain region, a channel region and a low concentration doped region, the channel region being formed between the source and drain regions, the low concentration doped region being formed both between the source and channel regions and between the drain and channel regions;
a first gate insulating layer formed on the semiconductor layer;
a second gate insulating layer formed on the first gate insulating layer to be overlapped with the low concentration doped region of the semiconductor layer and the channel region;
a first gate electrode formed on the second gate insulating layer to be overlapped with the channel region; and
a second gate electrode formed on the first gate electrode.

7. The TFT substrate of claim 6, wherein the second gate insulating layer comprises a first region formed in the low concentration doped region and a second region formed in the channel region,
and the first region is thinner than the second region.

8. The TFT substrate of claim 6, wherein the first gate electrode comprises at least one of titanium (Ti) and tantalum (Ta).

9. The TFT substrate of claim 6, wherein the second gate electrode comprises at least one of molybdenum (Mo) and tungsten (W).

10. The TFT substrate of claim 6, wherein the first gate insulating tayer comprises silicon oxide (SiOx).

11. The TFT substrate of claim 6, wherein the second gate insulating layer comprises silicon nitride (SiNx).

12. A method for manufacturing a TFT substrate, the method comprising:
forming a semiconductor layer on a base substrate;
forming a gate insulating layer on the semiconductor layer;
sequentially depositing first and second gate metal layers on the gate insulating layer;
coating a photoresist film on the second gate metal layer;
patterning the photoresist film via an exposure process;
forming a second gate electrode having a narrower width than that of the patterned photoresist film and a first gate electrode having substantially the same width as that of the patterned photoresist film, via etching of the first and second gate metal layers;
forming a source region and a drain region, via doping high concentration dopants on the semiconductor layer using the patterned photoresist film;
ashing the patterned photoresist film to have substantially the same width as that of the second gate electrode;
forming a first gate electrode to have substantially the same width as that of the second gate electrode, via etching of the first gate metal pattern;
removing the ashed photoresist film; and
forming a low concentration doped region, via doping low concentration dopants on the semiconductor layer using the first and second gate electrodes.

13. The method of claim 12, wherein forming the second gate electrode and the first gate metal pattern comprises:
forming the second gate electrode having the narrower width than that of the patterned photoresist film, via an isotropic etching process; and
forming the first gate electrode having substantially the same width as that of the patterned photoresist film, via an anisotropic etching process.

14. The method of claim 12, further comprising:
forming an insulating interlayer on the gate insulating layer and the second gate electrode, after forming the low concentration doped region;
forming first and second contact holes in the insulating interlayer for exposing the source region and the drain region;
forming a source electrode and a drain electrode that are electrically connected to the source and drain regions through the first and second contact holes, respectively;
forming a passivation layer on the source and drain electrodes;
forming a third contact hole in the passivation layer for exposing the drain electrode; and
forming a pixel electrode electrically connected to the drain electrode through the third contact hole.

15. The method of claim 12, wherein the first gate electrode comprises at least one of titanium (Ti) and tantalum (Ta).

16. A method for manufacturing a TFT substrate the method comprising:
forming a semiconductor layer on a base substrate;
sequentially forming first and second gate insulating layers on the semiconductor layer;
sequentially depositing first and second gate metal layers on the second gate insulating layer;
coating a photoresist film on the second gate metal layer;
patterning the photoresist film via an exposure process;
forming a second gate electrode having a narrower width than that of the patterned photoresist film and a first gate metal pattern having substantially the same width as that of the patterned photoresist film, via etching of the first and second gate metal layers.
patterning the second gate metal layer to have substantially the same width as that of the first gate metal pattern;
ashing the patterned photoresist film to have substantially the same width as that of the second gate electrode;
forming a first gate electrode to have substantially the same width as that of the second gate electrode, via etching of the first gate metal pattern;
removing the ashed photoresist film; and
simultaneously forming a low concentration doped region doped with dopants at a low concentration on the semiconductor layer, a source region and a drain region doped with the dopants at a high concentration on the semiconductor layer, using the first and second gate electrodes and the patterned second gate insulating layer.

17. The method of claim 16, wherein the first gate electrode includes at least one of titanium (Ti) and tantalum (Ta).
